(19) United States
(12) Patent Application Publication
(10) Pub. No.: US 2026/0237449 A1
(43) Pub. Date: Aug. 13, 2026

(54) TESTING ADAPTERS, TESTING SYSTEMS, AND TESTING METHODS FOR MEMORY APPARATUS

(71) Applicant: Yangtze Memory Technologies Co., Ltd., Wuhan (CN)

(72) Inventors: Haonan Chen, Wuhan (CN); Bin Zhang, Wuhan (CN); Guangjun Lyu, Wuhan (CN); Ming Gao, Wuhan (CN); Yiyang Jing, Wuhan (CN); Huayan Zhang, Wuhan (CN); Fang Ma, Wuhan (CN)

(21) Appl. No.: 19/360,567

(22) Filed: Oct. 16, 2025

(30) Foreign Application Priority Data
Feb. 12, 2025 (CN) 202510156625.5

(51) Int. Cl. G11C 29/14

(52) U.S. Cl. CPC G11C 29/14

(57) ABSTRACT

The present disclosure provides a testing adapter, testing system, and testing method for a memory apparatus. The testing adapter includes first to fourth interface circuits and first and second bridge chips, wherein the first and third interface circuits are configured to be connected to a host, respectively, and the second interface circuit is configured to be connected to a debugging information interface circuit of the memory apparatus, and the fourth interface circuit is configured to be connected to a data interface circuit of the memory apparatus; the first bridge chip is configured to be connected to the first and second interface circuits, the second bridge chip is configured to be connected to the first and fourth interface circuits; and the first and second bridge chips are configured to perform a testing operation on the memory apparatus based on a testing control instruction sent by the host.

### CROSS-REFERENCE TO RELATED APPLICATION

This application claims priority to and the benefit of Chinese Patent Application 202510156625.5, filed on Feb. 12, 2025, which is hereby incorporated by reference in its entirety.

### TECHNICAL FIELD

The present disclosure generally relates to the field of memory technology, and in particular to testing adapters, testing systems, and testing methods for memory apparatus.

### BACKGROUND

During a development process of a memory apparatus, it is usually necessary to test various functions and performance of the memory apparatus to verify whether the memory apparatus meets design requirements.

### BRIEF DESCRIPTION OF THE DRAWINGS

In order to provide a clearer explanation of the technical aspects in implementations of the present disclosure, a brief introduction will be given to the drawings required for the description of the implementations. The drawings described below are only some implementations of the present disclosure. Those skilled in the art will readily understand that other drawings may be obtained based on these drawings.

FIG. 1 is a schematic diagram of a system provided by an implementation of the present disclosure.

FIG. 2 is a schematic structural diagram of a memory card involved in the present disclosure.

FIG. 3 is a schematic structural diagram of a solid-state drive involved in the present disclosure.

FIG. 4 is a block diagram of a memory device according to an example implementation of the present disclosure.

FIG. 5 is a schematic circuit diagram of a memory device according to an example implementation of the present disclosure.

FIG. 6 is a cross-sectional side view of a memory string according to an example implementation of the present disclosure.

FIG. 7 is a structural diagram of a testing adapter for a memory apparatus provided in an example implementation of the present disclosure.

FIG. 8 is a structural diagram of a testing adapter for a memory apparatus provided in an example implementation of the present disclosure.

FIG. 9 is a structural diagram of a testing adapter for a memory apparatus provided in an example implementation of the present disclosure.

FIG. 10 is a structural diagram of a testing adapter for a memory apparatus provided in an example implementation of the present disclosure.

FIG. 11 is a structural diagram of a testing adapter for a memory apparatus provided in an example implementation of the present disclosure.

FIG. 12 is a structural diagram of a testing adapter for a memory apparatus provided in an example implementation of the present disclosure.

FIG. 13 is a structural diagram of a testing adapter for a memory apparatus provided in an example implementation of the present disclosure.

FIG. 14 is a structural diagram of a testing adapter involved in an implementation of the present disclosure.

FIG. 15 is a schematic diagram of a partial structure of a testing adapter involved in an implementation of the present disclosure.

FIG. 16 is a schematic diagram of a partial structure of a testing adapter involved in an implementation of the present disclosure.

FIG. 17 is a schematic diagram of an implementation process of power on/off control involved in an implementation of the present disclosure.

FIG. 18 is a schematic diagram of an implementation process of bias voltage control involved in an implementation of the present disclosure.

FIG. 19 is a schematic diagram of an implementation process of bias voltage control involved in an implementation of the present disclosure.

FIG. 20 is a schematic diagram of an implementation process of bias voltage control involved in an implementation of the present disclosure.

FIG. 21 is a flowchart of a testing method for a memory apparatus provided in an example implementation of the present disclosure.

### DETAILED DESCRIPTION

The following provides a further detailed description of implementations of the present disclosure in conjunction with the accompanying drawings.

A system, to which the memory apparatus involved in an implementation of the present disclosure is applied, may include a host and a memory system. The memory system may include a 3D memory device, such as a 3D NAND flash.

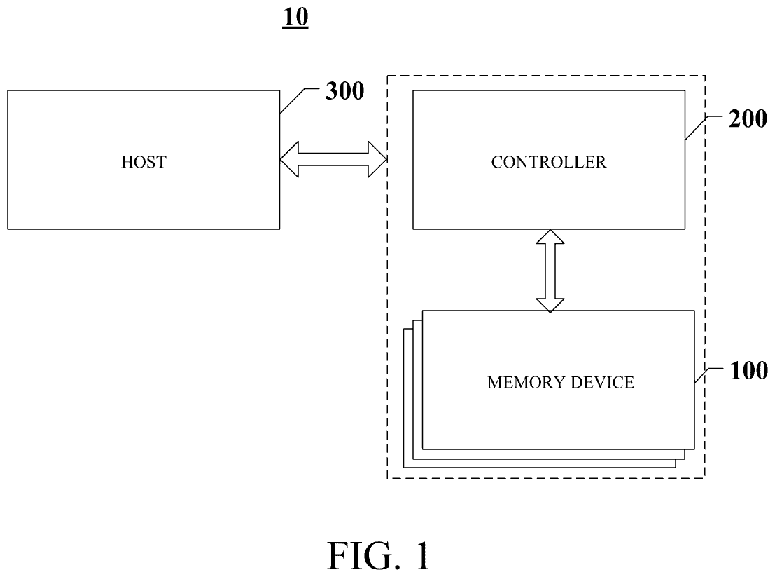

FIG. 1 is a schematic diagram of a system provided by an implementation of the present disclosure. As shown in FIG. 1, a computer system 10 includes one or more memory devices 100, and a controller 200 coupled to the memory devices 100 and configured to control the memory devices 100. The controller 200 may also be referred to as a memory controller.

The controller 200 may be configured to control operations performed on the memory device 100, for example, read, erase, and program operations. The controller 200 may also be configured to manage various functions with respect to data stored or to be stored in the memory device 100, including but not limited to bad block management, garbage collection, logical address to physical address conversion, wear leveling, etc. In an example, the controller 200 may also be configured to process error correcting codes (ECC) with respect to data read from or written to the memory device 100. The controller 200 may also perform any other suitable function, for example, formatting the memory device 100.

The controller 200 may also communicate with an external device according to a particular communication protocol. For example, the controller 200 may communicate with an external device through at least one of various interface protocols, such as Universal Serial Bus (USB) protocol, Multi-Media Card (MMC) protocol, Peripheral Component Interconnect (PCI) protocol, PCI express (PCI-E) protocol, Advanced Technology Attachment (ATA) protocol, Serial ATA protocol, Parallel ATA protocol, Small Computer System Interface (SCSI) protocol, Enhanced Small Drive Interface (ESDI) protocol, Integrated Development Environment (IDE) protocol, Fire wire protocol, etc.

In an example implementation, the controller 200 and one or more memory devices 100 may be integrated into various types of electronic devices. An electronic device may be a mobile phone, desktop computer, laptop computer, tablet computer, vehicle computer, game console, printer, positioning device, wearable electronic device, smart sensor, virtual reality (VR) device, augmented reality (AR) device, or any other suitable electronic device with a storage therein. In this scenario, as shown in FIG. 1, the computer system 10 further includes a host 300. The controller 200 is coupled to the host 300. The controller 200 may manage data stored in the memory device 100 and communicate with the host 300 to achieve functions of the aforementioned electronic devices.

In some other implementations, the controller 200 and one or more memory devices 100 may be integrated into various types of memory apparatuses.

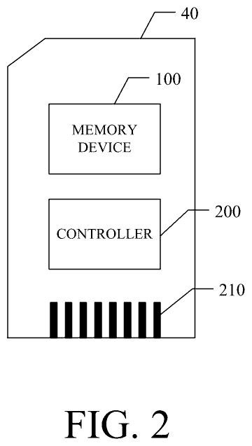

As an example, FIG. 2 is a schematic structural diagram of a memory card involved in the present disclosure. As shown in FIG. 2, the controller 200 and a single memory device 100 may be integrated into a memory card 40. The memory card 40 may include Personal Computer Memory Card International Association (PCMCIA, PC) card, Compact Flash (CF) card, Smart Media (SM) card, memory stick, Multi-Media Card (MMC), Reduced-Size MMC (RS-MMC), Micro-MMC, Secure Digital (SD) card, Universal Flash storage (UFS), etc. As shown in FIG. 2, the memory card 40 may further include a connector 210 that couples the memory card 40 with a host.

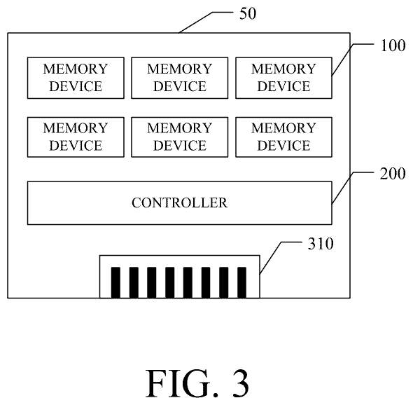

As another example, FIG. 3 is a schematic structural diagram of a solid-state drive involved in the present disclosure. As shown in FIG. 3, the controller 200 and multiple memory devices 100 may be integrated into a Solid State Disk (SSD) 50. The solid-state drive 50 may further include a connector 310 that couples the solid-state drive 50 with a host. The memory capacity and/or operating speed of the solid state drive 50 are greater than those of the memory card 40.

In addition, the memory device 100 in FIGS. 1 to 3 may be any memory device involved in implementations of the present disclosure, such as a 3D NAND (NOT AND) memory device. An explanation of the structure of the memory device 100 is given below.

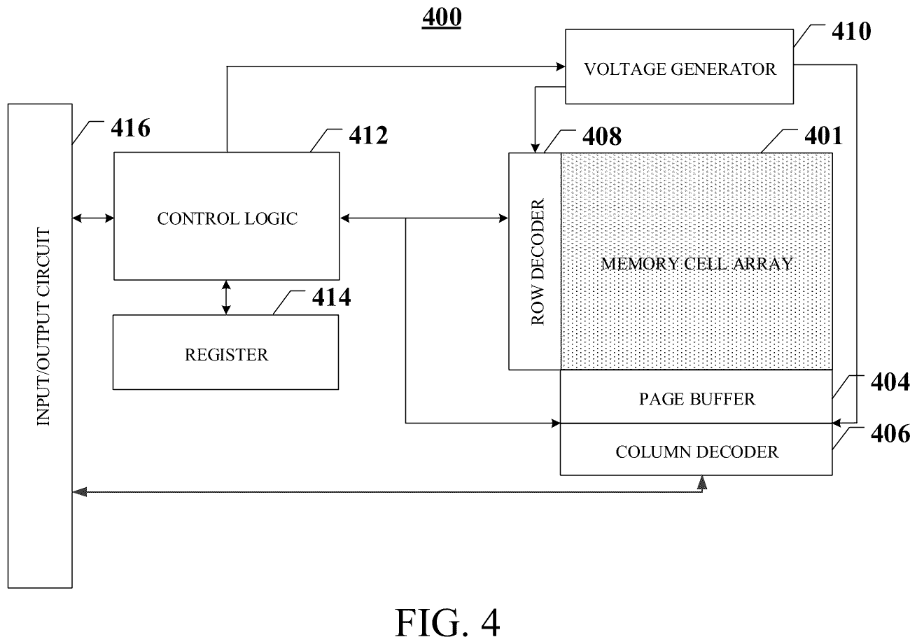

FIG. 4 is a block diagram of a memory device according to an example implementation of the present disclosure. Referring to FIG. 4, the memory device 400 may include a memory cell array 401, a page buffer 404, a column decoder 406, a row decoder 408, a voltage generator 410, control logic 412, register 414, and input/output circuit 416. It should be understood that in some examples, an additional peripheral circuit not shown in FIG. 4 may also be included.

The page buffer 404 may be configured to read data from the memory cell array 401 and program (write) data to the memory cell array 401 based on a control signal from the control logic 412. In one example, the page buffer 404 may store data (written data) to be programmed into a selected page of the memory cell array 401. In another example, the page buffer 404 may output the read data during a program verification operation to ensure that the data has been correctly programmed into a corresponding memory cell coupled to a selected word line of the memory cell array 401. The column decoder 406 may operate in response to a control signal provided by the control logic to select one or more memory strings in the memory cell array 401. The row decoder may operate in response to a control signal provided by the control logic and select/deselect a selected row of the memory cell array 401. The row decoder may also be configured to supply a voltage generated from the voltage generator 410 to the selected and unselected word lines of the memory cell array 401. As described in detail below, the row decoder 408 is configured to perform an erase operation on memory cells coupled to one or more selected word lines in the memory cell array 401. The voltage generator 410 may use external or internal power supply voltages to generate various voltages required by the memory device, such as programming voltage, read voltage, pass voltage, verify voltage, bit line voltage, and a combination thereof.

The control logic 412 may be coupled to voltage generator 410, page buffer 404, column decoder 406, row decoder 408, input/output circuit 416, and the like, and configured to control operations of various peripheral circuits. The control logic may generate an operation signal in response to a command or control signal from the memory controller. The register 414 may be coupled to control logic 412 and may include a status register, a command register, and an address register for storing status information, command operation codes (OP codes), and command addresses used to control operations of each peripheral circuit. The input/output circuit 416 may be coupled to the control logic 412 and act as a control buffer to buffer a control command received from an external device (such as host 300 or controller 200 in FIG. 1) and relay it to the control logic 412, and buffer status information received from the control logic 412 and relay it to the host. The input/output circuit 416 may also be coupled to a column decoder and serve as a data input/output interface and data buffer to buffer data and relay it to the memory cell array 401 or relay or buffer data from the memory cell array 401.

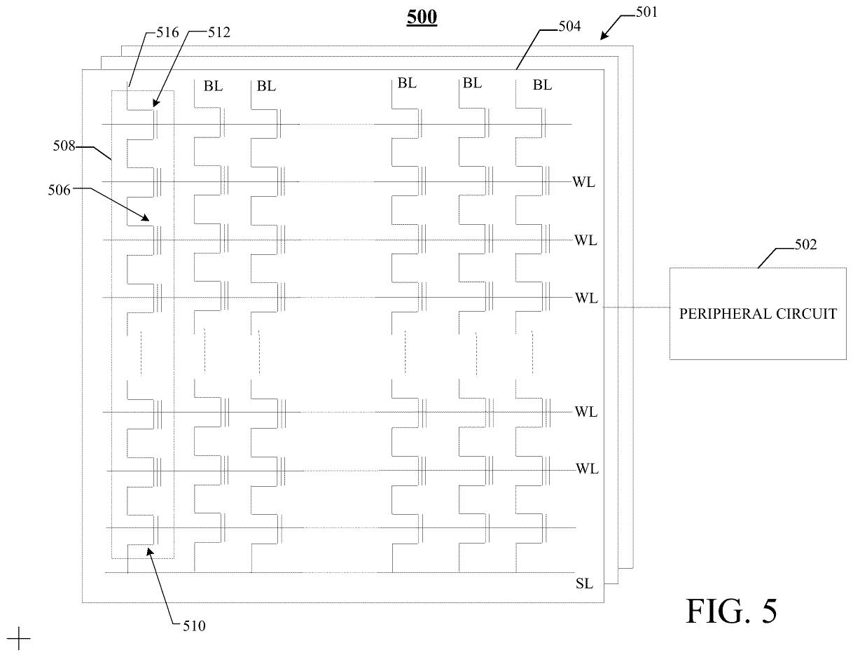

FIG. 5 is a schematic circuit diagram of a memory device according to an example implementation of the present disclosure. As shown in FIG. 5, the memory device 500 may include a memory cell array 501 and a peripheral circuit 502 coupled to the memory cell array 501. The memory cell array 501 may be a NAND flash memory cell array, wherein the memory cells 506 are provided in the form of an array of memory strings 508, each of which extends vertically above a substrate (not shown). In some implementations, each memory string 508 includes multiple memory cells 506 coupled in series and stacked vertically. Each memory cell 506 may be a floating gate type memory cell including a floating gate transistor, or a charge trapping type memory cell including a charge trapping transistor. In some implementations, each memory cell 506 is a single level cell (SLC) having two possible memory states (or memory states) that may store one bit of data. For example, the first memory state ‘0’ may correspond to a first voltage range, and the second memory state ‘1’ may correspond to a second voltage range. In some implementations, each memory cell 506 is a multi-level unit capable of storing more than a single bit of data in more than two memory states, for example, two bits per cell (e.g., Multi-Level Cell (MLC)), three bits per cell (e.g., Triple-Level Cell (TLC)), or four bits per cell (e.g., Quad-Level Cell (QLC)).

As shown in FIG. 5, each memory string 508 may include at least one source select transistor 510 at its source terminal and at least one drain select transistor 512 at its drain terminal. The source select transistor 510 and the drain select transistor 512 may be configured to activate the selected memory string 508 during read and program operations. In some implementations, the sources of memory strings 508 in the same block 504 are coupled through the same source line (SL). According to some implementations, the drain select transistor 512 of each memory string 508 is coupled to a corresponding bit line 516. In some implementations, each memory string 508 is configured to be selected or deselected by applying a selection voltage or deselection voltage (e.g., 0V) to the corresponding drain select transistor 512 via one or more drain select lines and/or by applying a selection voltage or deselection voltage (e.g., 0V) to the corresponding source select transistor 510 via one or more source select lines.

As shown in FIG. 5, a memory cell array may include multiple blocks. In some implementations, each block 504 is a basic data unit for erasing operations; that is, all memory cells 506 on the same block 504 are erased simultaneously.

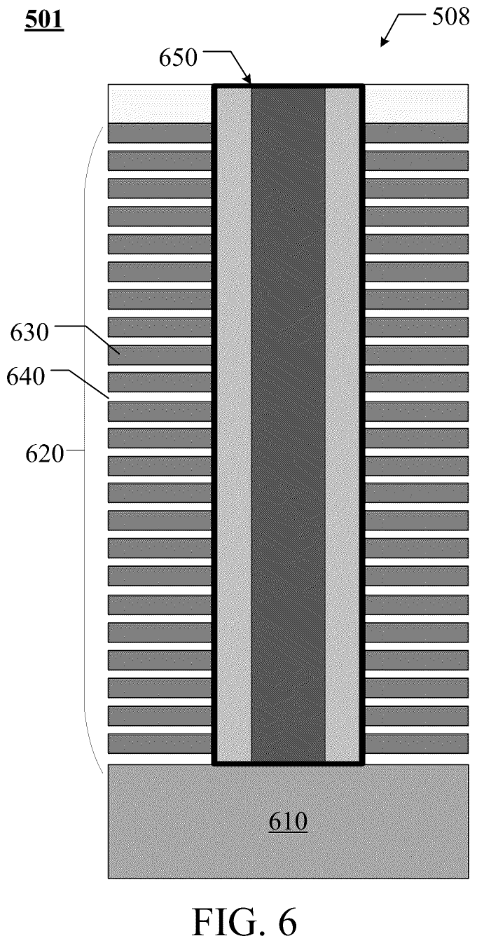

FIG. 6 is a cross-sectional side view of a memory cell array 501 including a memory string 508 according to one implementation of the present disclosure. Referring to FIG. 6, the memory string 508 may extend vertically through the stacked layer 620 above the semiconductor layer 610. The semiconductor layer 610 is coupled to the source line. In some implementations, the semiconductor layer 610 is an N-type doped semiconductor layer, and may serve as a substrate, e.g., an N-type substrate. In some other implementations, the semiconductor layer 610 is a P-type doped semiconductor layer, and may be a P-well in a substrate, which is a P-type substrate.

The stacked layer 620 includes multiple conductive layers 630 and multiple dielectric layers 640 stacked alternately. The number of pairs of the conductive layer 630 and the dielectric layer 640 in the stacked layer 620 may affect the number of memory cells in the memory string. The conductive layer 630 may include a conductive material, including but not limited to tungsten (W), cobalt (Co), copper (Cu), aluminum (Al), polycrystalline silicon, doped silicon, silicide, or any combination thereof. In one possible implementation, each conductive layer 630 includes a metal layer, such as a tungsten layer. In some implementations, each conductive layer 630 includes a doped polycrystalline silicon layer. Each conductive layer 630 may include a gate surrounding the memory cell and may extend laterally as a drain select line (DSL) at the top of the stacked layer 620, as a source select line (SSL) at the bottom of the stacked layer 620, or as a word line (WL) between the DSL and SSL.

As shown in FIG. 6, the memory string 508 includes a channel structure 650 vertically extending through the stacked layer 620. The channel structure 650 includes a channel hole filled with at least one semiconductor material (such as a semiconductor channel) and at least one dielectric material (such as a memory film). In some implementations, the semiconductor channel includes silicon (such as a memory film). In some implementations, the memory film is a composite dielectric layer comprising a tunnel layer, a trap layer, and a barrier layer. The channel structure 650 may have a cylindrical shape (such as a columnar shape). According to some implementations, the semiconductor channel, trap layer (also known as a memory layer), and barrier layer are arranged radially from the center of the cylinder towards the outer surface of the cylinder in this order. The tunnel layer may include silicon oxide, silicon oxynitride, or any combination thereof. The trap layer may include silicon nitride, silicon oxynitride, or any combination thereof. The barrier layer may include silicon oxide, silicon oxynitride, high dielectric constant (high k) dielectric, or any combination thereof. In one example, the memory film may include a composite layer of silicon oxide/silicon oxynitride/silicon oxide.

For technical details of hardware implementations related to the above memory device which are not disclosed here, please refer to the description of computer system implementations and method implementations in the present disclosure for understanding.

The memory apparatuses involved in each implementation of the present disclosure may include the above-mentioned memory system, or the memory apparatuses involved in implementations of the present disclosure may include the memory device in the above-mentioned memory system.

For example, the above-mentioned memory apparatuses may be Solid State Disk (SSD), such as Enterprise SSD (eSSD) or Consumer SSD (cSSD).

In some implementations, during testing of a memory apparatus, for different functions or testing items of the memory apparatus, a tester may use different testing tools for testing. For example, for a serial port function and Universal Asynchronous Receiver/Transmitter (UART) function of a testing device, the tester may use a serial port and a Joint Test Action Group (JTAG) test card for testing; for a peripheral component interconnect express (PCIe) function of the testing device, the tester may use a PCIe test card for testing; and for a voltage bias and voltage/current sampling function, the tester may use an adapter card and external acquisition device (such as a current and voltage tester) for testing. During a testing process of a memory apparatus, developers may use a testing card integrated with a Micro Controller Unit (MCU) to perform testing on the memory apparatus. The testing of a part of the above-mentioned functions relies on the MCU to execute. For example, if the MCU is provided in the test card/adapter card, the tester may develop an MCU-based testing instruction. During the testing process, the host sends a testing instruction to the MCU in the test card/adapter card, and the MCU in the test card/adapter card executes the testing instruction to perform corresponding tests on the memory apparatus.

However, in the aspects illustrated in the above-mentioned implementations of the present disclosure, the development process of an MCU-based testing instruction is relatively complex, resulting in a cumbersome testing process for a memory apparatus and affecting the testing efficiency of the memory apparatus.

For the above issues, the aspects illustrated in the subsequent implementations of the present disclosure provide a testing adapter for a memory apparatus. The testing adapter does not rely on the MCU, but achieves testing of the memory apparatus through a bridge chip, which may simplify the complexity of testing a memory apparatus and improve the efficiency of testing the memory apparatus.

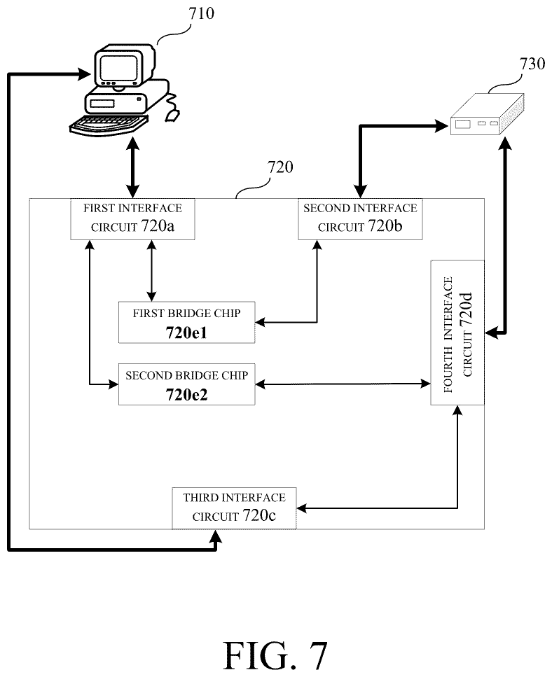

Please refer to FIG. 7, which is a structural diagram of a testing adapter for a memory apparatus provided in an example implementation of the present disclosure. As shown in FIG. 7, the testing adapter 720 may include a first interface circuit 720a, a second interface circuit 720b, a third interface circuit 720c, a fourth interface circuit 720d, a first bridge chip 720e1, and a second bridge chip 720e2.

In the first interface circuit 720a, the second interface circuit 720b, the third interface circuit 720c, and the fourth interface circuit 720d, each interface circuit may correspond to one of multiple different communication interface standards. The multiple different communication interface standards may include but are not limited to: Universal Serial Bus (USB) interface standard (such as USB2.0, USB3.0, Type-C, etc.), High Definition Multimedia Interface (HDMI) standard, Micro HDMI standard, U.2 interface standard, M.2 interface standard, and Add-In-Card (AIC) interface standard.

The first bridge chip 720e1 and the second bridge chip 720e2 are two independent bridge chips. The bridge chip, also known as bridging chip, is an integrated circuit for connecting interfaces/devices/systems of different types or standards.

The first interface circuit 720a and the third interface circuit 720c are respectively configured to be connected to the host 710. The second interface circuit 720b is configured to be connected to a debugging information interface circuit of the memory apparatus 730. The fourth interface circuit 720d is configured to be connected to a data interface circuit of the memory apparatus 730.

In some implementations, the host 710 is a host in a testing platform for performing testing on a memory apparatus. In other implementations, the host 710 is the host 300 shown in FIG. 1.

The first interface circuit 720a and the third interface circuit 720c are respectively configured to be connected to interface circuits in the host 710 corresponding to the interface standards of the first interface circuit 720a and the third interface circuit 720c.

For example, in an example in which the first interface circuit 720a is an interface circuit adopting a USB interface standard (such as a Type-C interface circuit) and the third interface circuit 720c is a U.2 interface circuit (also known as a U.2 connector), the first interface circuit 720a is configured to be connected to the Type-C interface circuit in the host, and the third interface circuit 720c is configured to be connected to the U.2 interface circuit in the host.

The debugging information interface circuit of the memory apparatus 730 is an interface circuit for receiving a debugging signal and outputting debugging information in the memory apparatus 730.

The data interface circuit of the memory apparatus 730 is an interface circuit for transmitting and receiving data in the memory apparatus 730.

The interface standard of the second interface circuit 720b corresponds to the interface standard of the debugging information interface circuit, and the interface standard of the fourth interface circuit 720d corresponds to the interface standard of the data interface circuit.

For example, the second interface circuit 720b and the debugging information interface circuit are each HDMI interface circuits or Micro HDMI interface circuits, and the fourth interface circuit 720d and the data interface circuit are each U.2 interface circuits or M.2 interface circuits.

The first bridge chip 720e1 is configured to be connected to the first interface circuit 720a, and be connected to the second interface circuit 720b. The second bridge chip 720e2 is configured to be connected to the first interface circuit 720a, and be connected to the fourth interface circuit 720d.

The first bridge chip 720e1 is connected to the first interface circuit 720a and the second interface circuit 720b. The first bridge chip 720e1 may achieve data transmission, communication, or coordinated operation between the host 710 and the debugging information interface circuit of the memory apparatus 730.

The first bridge chip 720e1 may be directly or indirectly connected to the first interface circuit 720a. The first bridge chip 720e1 may be directly or indirectly connected to the second interface circuit 720b.

The second bridge chip 720e2 is connected to the first interface circuit 720a and the fourth interface circuit 720d. The second bridge chip 720e2 may achieve data transmission, communication, or coordination operations between the host 710 and the data interface circuit of the memory apparatus 730.

The second bridge chip 720e2 may be directly or indirectly connected to the first interface circuit 720a. The second bridge chip 720e2 may be directly or indirectly connected to the fourth interface circuit 720d.

The indirect connection mentioned above refers to the presence of other integrated circuits or components between the bridge chip and the interface circuit.

In some implementations, the first bridge chip 720e1 and the second bridge chip 720e2 may be connected to the first interface circuit 720a through a hub chip. In an example, the first interface circuit 720a is connected to one port/pin of the hub chip, and the first bridge chip 720e1 and the second bridge chip 720e2 are respectively connected to the other two ports/pins of the hub chip.

The first bridge chip 720e1 and the second bridge chip 720e2 are configured to perform a testing operation on the memory apparatus 730 based on the testing control instruction sent by the host 710.

In the implementation of the present disclosure, the first bridge chip 720e1 and the second bridge chip 720e2 may control testing operations of the memory apparatus 730 when implementing data transmission, communication, or coordination operations between different interface circuits.

In summary, the aspects illustrated in implementations of the present disclosure provides a testing adapter for testing a memory apparatus. The testing adapter is connected to a host and a memory apparatus through four interface circuits, respectively, and includes a first bridge chip and a second bridge chip that are connected to the four interface circuits, respectively. During the testing process of the memory apparatus, the first bridge chip and the second bridge chip in the testing adapter may perform a testing operation on the memory apparatus based on the testing control instruction sent by the host. In the above aspect, the testing adapter does not rely on MCU, and instead uses bridge chips to test the memory apparatus. Compared to a test card that relies on MCU, the circuit complexity of the testing adapter provided in the present disclosure is lower. Correspondingly, when using the testing adapter to test a memory apparatus, complex software control logic is not required, resulting in lower testing complexity and improved testing efficiency for the memory apparatus.

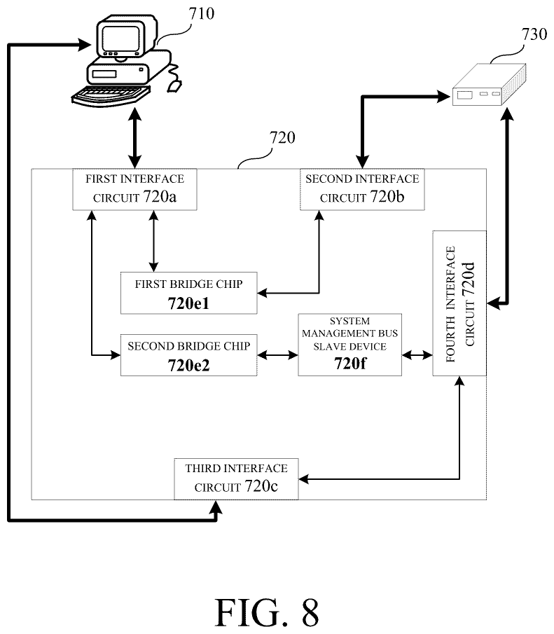

Based on the aspects illustrated in any one or more of the above implementations, in some implementations, please refer to FIG. 8, which illustrates a structural diagram of a testing adapter involved in an implementation of the present disclosure. As shown in FIG. 8, the testing adapter 720 further includes at least one System Management Bus (SMBus) slave device 720f. The second bridge chip 720e2 is configured to be connected to the at least one system management bus slave device 720f. The at least one system management bus slave device 720f is configured to be connected to the fourth interface circuit 720d.

The system management bus slave device 720f is an integrated circuit/component that supports SMBus communication protocol, and different system management bus slave devices 720f may have different circuit functions.

In the implementation of the present disclosure, one or more system management bus slave devices 720f may be provided between the second bridge chip 720e2 and the fourth interface circuit 720d in the testing adapter 720. Different system management bus slave devices 720f may achieve different expansion functions, thereby expanding the testing modes for a memory apparatus through the testing adapter 720.

Based on the aspects illustrated in any one or more of the above implementations, in some implementations, the first bridge chip 720e1 is configured to receive from the first interface circuit 720a a first control instruction from the host 710, and send the first control instruction to the memory apparatus 730 through the second interface circuit 720b after converting a format of the first control instruction into a format of a protocol corresponding to the second interface circuit 720b. The first control instruction instructs the memory apparatus 730 to perform a first testing-related operation. The first bridge chip 720e1 is configured to receive from the second interface circuit 720b debugging information sent by the memory apparatus 730, and send the debugging information to the host 710 through the first interface circuit 720a after converting a format of the debugging information into a format of a protocol corresponding to the first interface circuit 720a.

The debugging information may be information related to the first operation in memory apparatus 730. For example, the debugging information may include records, operation results, and other related information of the first operation performed by memory apparatus 730. In an example, the debugging information may further include other information beyond the information related to the first operation. For example, the debugging information may include one or more specified state information of the memory apparatus 730.

In the implementation of the present disclosure, when a tester needs to trigger the memory apparatus 730 to perform the first testing-related operation, the host 710 may send the first control instruction to the first interface circuit 720a in the testing adapter 720, and the first bridge chip 720e1 may receive the first control instruction from the first interface circuit 720a, and determine from the identification of the first control instruction (such as a destination address) that the first control instruction is an instruction which is to be sent to the memory apparatus 730 through the second interface circuit 720b. At this time, the first bridge chip 720e1 may perform format conversion on the first control instruction for converting a format of the first control instruction from a format of a protocol corresponding to the first interface circuit 720a to a format of a protocol corresponding to the second interface circuit 720b, and send the format-converted first control instruction to the memory apparatus 730 through the second interface circuit 720b, so that the memory apparatus 730 may parse the first control instruction and perform the first operation based on the first control instruction.

Correspondingly, the memory apparatus 730 may transmit the debugging information to the host 710 through the second interface circuit 720b and the first interface circuit 720a. For example, the memory apparatus 730 may send debugging information to the second interface circuit 720b in the testing adapter 720, and the first bridge chip 720e1 may receive the debugging information from the second interface circuit 720b, and determine from the identification of the debugging information (such as a destination address) that the debugging information is an instruction which is to be sent to the host 710 through the first interface circuit 720a, and then convert a format of the debugging information from a format of a protocol corresponding to the second interface circuit 720b to a format of a protocol corresponding to the first interface circuit 720a, and send the format-converted debugging information to the host 710 through the first interface circuit 720a, so that the host 710 may parse the debugging information.

For example, in an example in which the first interface circuit 720a is a Type-C interface circuit and the second interface circuit 720b is a Micro HDMI interface circuit, the host 710 may send the first control instruction (in USB protocol format) to the first interface circuit 720a in the testing adapter 720. The first bridge chip 720e1 may receive the first control instruction (in USB protocol format) from the first interface circuit 720a, convert a format of the first control instruction (in USB protocol format) into UART protocol format, and send the format-converted first control instruction (in UART protocol format) to the memory apparatus 730 through the second interface circuit 720b. Correspondingly, the memory apparatus 730 sends debugging information (in UART protocol format) to the second interface circuit 720b, and the first bridge chip 720e1 converts a format of debugging information from UART protocol format to USB protocol format, and sends the debugging information (in USB protocol format) to the host 710 through the first interface circuit 720a.

In the aspects illustrated in the above implementations of the present disclosure, a format conversion and transmission of a control instruction and debugging information may be executed between the host 710 and the memory apparatus 730 by the first bridge chip 720e1, thereby accurately transmitting a test-related control instruction and debugging information between the host 710 and the memory apparatus 730. Control and debugging information reading of the memory apparatus may be achieved without relying on MCU, the complexity of testing the memory apparatus may be simplified, and the efficiency of testing the memory apparatus may be improved.

Based on the aspects illustrated in any one or more of the above implementations, in some implementations, the first control instruction includes at least one of: an instruction to perform Universal Asynchronous Receiver/Transmitter (UART) testing; an instruction to perform Joint Test Action Group (JTAG) testing; and an instruction to perform Non-volatile Memory Expansion Management Interface (NVMe-MI) circuit testing related to Peripheral Component Interconnect Extension (PCI-E).

The instruction to perform UART testing may instruct the memory apparatus 730 to perform an operation related to UART communication testing, such as performing specified transmission operations through a UART serial port.

The instruction to perform Joint Test Action Group (JTAG) testing may instruct the memory apparatus 730 to perform an operation related to JTAG testing. The information about the operation related to JTAG testing (such as test mode, test parameters, or the like) may be pre-set in the host 710 by the tester and transmitted to the memory apparatus 730 through the JTAG testing instruction.

The instruction to perform NVMe-MI testing related to PCI-E may instruct the memory apparatus 730 to perform an operation related to NVMe-MI testing, such as instructing the memory apparatus 730 to send data to the host 710 based on NVMe-MI, and so on.

In the aspects illustrated in the above implementations of the present disclosure, the transmission of a control instruction for testing items such as UART testing, JTAG testing, NVMe-MI protocol testing, or the like may be performed between the host 710 and the memory apparatus 730 by the first bridge chip 720e1. In other words, the testing adapter provided in implementations of the present disclosure may perform multiple different testing items without requiring a tester to use different testing cards/adapters to achieve different testing functions, thereby simplifying the complexity of testing a memory apparatus and improving the efficiency of testing the memory apparatus.

Based on the aspects illustrated in any one or more of the above implementations, in some implementations, the second bridge chip 720e2 is configured to receive from the first interface circuit 720a a second control instruction from the host 710, and send the second control instruction to a target slave device after converting a format of the second control instruction into a format of a system management bus protocol, wherein the target slave device is one or more of the at least one system management bus slave device 720f. The target slave device is configured to perform a second testing-related operation based on the second control instruction.

The system management bus slave device 720f is an integrated circuit/component that supports the SMBus protocol, and a format of the instruction sent by the host 710 to the first interface circuit 720a is generally not the SMBus protocol format. In this regard, when the tester needs to trigger the target slave device to perform a second testing-related operation, a second control instruction may be sent to the first interface circuit 720a in the testing adapter 720 by the host 710. The second bridge chip 720e2 may receive the second control instruction from the first interface circuit 720a, and determine from the identification of the second control instruction (such as a destination address) that the second control instruction is an instruction which is to be sent to the target slave device. At this time, the second bridge chip 720e2 may perform format conversion on the second control instruction for converting a format of the second control instruction from a format of a protocol corresponding to the first interface circuit 720a to a format of SMBus protocol, and send the format-converted second control instruction to the target slave device, so that the target slave device may parse the second control instruction, and perform a second operation based on the second control instruction.

The second operation mentioned above may be a functional operation that the target device itself has/is designed to perform.

In the implementation of the present disclosure, a format conversion and transmission of a control instruction and debug information are performed between the host 710 and the memory apparatus 730 by the second bridge chip 720e2, thereby accurately transmitting the testing-related control instruction between the host 710 and the system management bus slave device 720f to trigger the system management bus slave device 720f to perform a corresponding testing operation, and achieving flexible control of a specified slave device in the testing adapter to perform a specified testing operation and improving the flexibility of testing the memory apparatus.

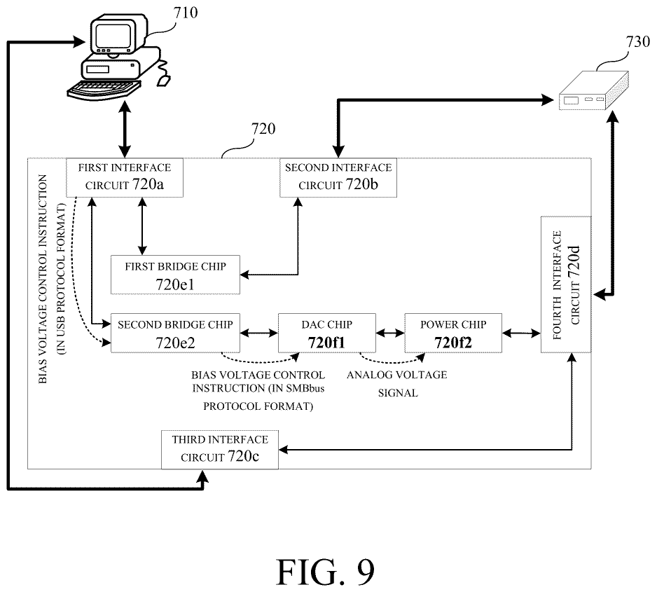

Based on the aspects illustrated in any one or more of the above implementations, in some implementations, please refer to FIG. 9, which illustrates a structural diagram of a testing adapter involved in an implementation of the present disclosure. As shown in FIG. 9, at least one system management bus slave device 720f includes a digital-to-analog converter (DAC) chip 720f1 and a power chip 720f2. The second bridge chip 720e2 is configured to be connected to the DAC chip 720f1, the DAC chip 720f1 is configured to be connected to the power chip 720f2, and the power chip 720f2 is configured to be connected to the fourth interface circuit 720d. In the case where the second control instruction includes a bias voltage control instruction, the second bridge chip 720e2 is configured to send the bias voltage control instruction to the DAC chip 720f1 after converting a format of the bias voltage control instruction into a format of a system management bus protocol; the DAC chip 720f1 is configured to send an analog voltage signal to the power chip 720f2 after converting a digital voltage signal corresponding to the bias voltage control instruction into the analog voltage signal; and the power chip 720f2 is configured to control a voltage output to the fourth interface circuit 720d based on the analog voltage signal.

The DAC chip 720f1 has a function of digital to analog conversion (converting a digital signal into an analog signal). The power chip 720f2 has a function of supplying power to the fourth interface circuit.

In the above implementation, a tester may control, by the host 710, the system management bus slave device 720f in the testing adapter to perform a testing operation controlled by a bias voltage. For example, the tester may send, by the host 710, a bias voltage control instruction to the first interface circuit 720a in the testing adapter 720, and the second bridge chip 720e2 may receive the bias voltage control instruction from the first interface circuit 720a, and determine from the identification of the bias voltage control instruction (such as a destination address) that the bias voltage control instruction is an instruction which is to be sent to the DAC chip 720f1. At this time, the second bridge chip 720e2 may perform format conversion on the bias voltage control instruction, convert a format of the bias voltage control instruction from a format of a protocol corresponding to the first interface circuit 720a to a format of SMBus protocol, and send the format-converted bias voltage control instruction to the DAC chip 720f1, so that the DAC chip 720f1 may parse and identify a digital voltage signal in the bias voltage control instruction. The DAC chip 720f1 sends an analog voltage signal to the power chip 720f2 after converting the digital voltage signal into the analog voltage signal to control the power chip 720f2 to output a voltage corresponding to the analog voltage signal to the fourth interface circuit 720d.

For example, in an example in which the first interface circuit 720a is a Type-C interface circuit, the host 710 may send a bias voltage control instruction (in USB protocol format) to the first interface circuit 720a in the testing adapter 720, and the second bridge chip 720e2 may receive the bias voltage control instruction (in USB protocol format) from the first interface circuit 720a, convert a format of the bias voltage control instruction (in USB protocol format) into SMBus protocol format, and send the format-converted bias voltage control instruction (in SMBus protocol format) to the DAC chip 720f1. The DAC chip 720f1 sends an analog voltage signal to the power chip 720f2 after converting a digital voltage signal in the bias voltage control instruction into the analog voltage signal.

In the implementation of the present disclosure, the DAC chip 720f1 and the power chip 720f2 are built into the testing adapter, and the target voltage set at the host 710 is accurately transmitted to the power chip 720f2 by the second bridge chip 720e2, ensuring the accuracy and flexibility of bias voltage control during the testing process.

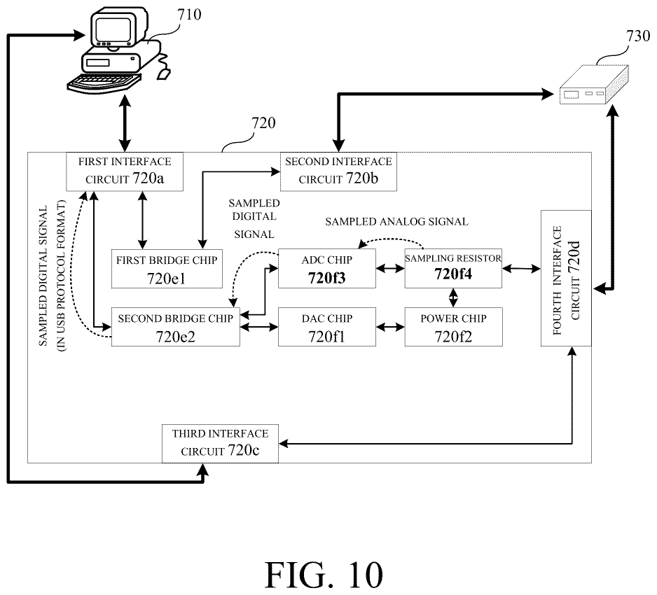

Based on the aspects illustrated in any one or more of the above implementations, in some implementations, please refer to FIG. 10, which illustrates a structural diagram of a testing adapter involved in an implementation of the present disclosure. As shown in FIG. 10, at least one system management bus slave device 720f further includes an analog-to-digital converter (ADC) chip 720f3 and a sampling resistor 720f4. The second bridge chip 720e2 is configured to be connected to the ADC chip 720f3, and the ADC chip 720f3 is configured to be connected to the sampling resistor 720f4, wherein the sampling resistor 720f4 is in a circuit between the power chip 720f2 and the fourth interface circuit 720d. In the case where the second control instruction includes a sampling instruction, the second bridge chip 720e2 is configured to send the sampling instruction to the ADC chip 720f3 after converting a format of the sampling instruction into a format of the system management bus protocol. The ADC chip 720f3 is configured to sample at least one of a voltage and a current of the sampling resistor 720f4 to obtain a sampled analog signal, convert the sampled analog signal into a sampled digital signal, and send the sampled digital signal to the second bridge chip 720e2 based on the sampling instruction. The second bridge chip 720e2 is further configured to send the sampled digital signal to the host 710 through the first interface circuit 720a after converting a format of the sampled digital signal to a format of a protocol corresponding to the first interface circuit 720a.

The ADC chip 720f3 has a function of analog-to-digital conversion (converting an analog signal into a digital signal), meanwhile the ADC chip 720f3 also has a function of performing voltage/current acquisition based on the sampling resistor 720f4. When the sampled analog signal includes an analog signal of a sampled voltage, the sampled voltage may be a power supply voltage output by the power chip 720f2 to the fourth interface circuit 720d, or the sampled voltage may be a voltage across the sampling resistor 720f4. The host 710 may infer/calculate the power supply voltage output by the power chip 720f2 to the fourth interface circuit 720d based on the voltage across the sampling resistor 720f4. When the sampled analog signal includes an analog signal of a sampled current, the sampled current may be the current supplied to the memory apparatus through the fourth interface circuit 720d.

In the above implementation, a tester may control, by the host 710, the system management bus slave device 720f in the testing adapter to perform a testing operation of voltage/current sampling. For example, the tester may send, by the host 710, a sampling instruction to the first interface circuit 720a in the testing adapter 720, and the second bridge chip 720e2 may receive the sampling instruction from the first interface circuit 720a, and determine from the identification of the sampling instruction (such as a destination address) that the sampling instruction is an instruction which is to be sent to the ADC chip 720f3. At this time, the second bridge chip 720e2 may perform format conversion on the sampling instruction for converting a format of the sampling instruction from a format of a protocol corresponding to the first interface circuit 720a to a format of SMBus protocol, and send the format-converted sampling instruction to the ADC chip 720f3, so that the ADC chip 720f3 may parse and identify the sampling instruction. The ADC chip 720f3 may perform sampling on at least one of a voltage and a current of the sampling resistor 720f4 to obtain a sampled analog signal, convert the sampled analog signal into a sampled digital signal, and send the sampled digital signal to the second bridge chip 720e2. The second bridge chip 720e2 may identify from the identification of the sampled digital signal (such as source address, destination address, or signal type) that the sampled digital signal is a signal which is to be sent to the host 710, and sends the sampled digital signal to the host 710 through the first interface circuit 720a after converting a format of the sampled digital signal to a format of a protocol corresponding to the first interface circuit 720a.

For example, in an example in which the first interface circuit 720a is a Type-C interface circuit, the host 710 may send a sampling instruction (in USB protocol format) to the first interface circuit 720a in the testing adapter 720, and the second bridge chip 720e2 may receive the sampling instruction (in USB protocol format) from the first interface circuit 720a, convert a format of the sampling instruction (in USB protocol format) into SMBus protocol format, and send the format-converted sampling instruction (in SMBus protocol format) to the ADC chip 720f3. The ADC chip 720f3 samples a current or voltage from the sampling resistor 720f4 to obtain a sampled analog signal of the current or voltage, converts the sampled analog signal into a sampled digital signal (in SMBus protocol format), and sends the sampled digital signal to the second bridge chip 720e2. The second bridge chip 720e2 sends the sampled digital signal to the host 710 through the first interface circuit 720a after converting a format of the sampled digital signal to the USB protocol format.

In the implementation of the present disclosure, the ADC chip 720f3 and the sampling resistor 720f4 are built into the testing adapter, the sampled signal set at the host 710 is accurately transmitted to the ADC chip 720f3 by the second bridge chip 720e2, and the sampled digital signal obtained by the ADC chip 720f3 is also accurately transmitted to the host 710 by the second bridge chip 720e2, during which an external acquisition device may be configured to sample the voltage and current of the memory apparatus, simplifying the complexity of voltage and current sampling and ensuring the execution efficiency and flexibility of voltage and current sampling in the testing process.

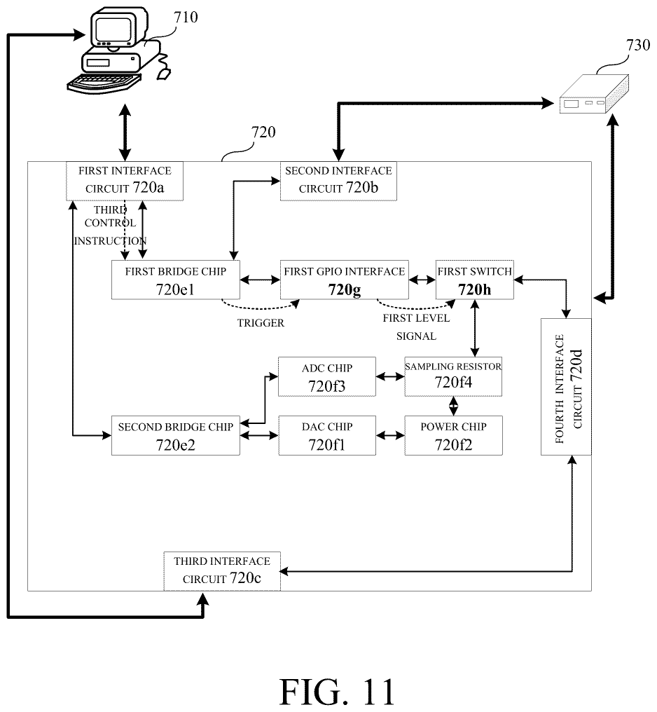

Based on the aspects illustrated in any one or more of the above implementations, in some implementations, please refer to FIG. 11, which illustrates a structural diagram of a testing adapter involved in an implementation of the present disclosure. As shown in FIG. 11, the testing adapter 720 further includes a first General Purpose Input/Output (GPIO) interface circuit 720g and a first switch 720h. The first GPIO interface circuit 720g is configured to be connected to a first target chip, and be connected to the first switch 720h. The first switch 720h is in a power supply circuit of the testing adapter 720 for supplying power to the memory apparatus 730. The first target chip may be one of the first bridge chip 720e1 and the second bridge chip 720e2, and as shown in FIG. 11, the first target chip is the first bridge chip 720e1. The first target chip is configured to receive from the first interface circuit 720a a third control instruction from the host 710, and trigger the first GPIO interface circuit 720g to send a first level signal to the first switch 720h based on the third control instruction. The first level signal is configured to trigger the first switch 720h to disconnect or connect, for controlling the power on/off of the memory apparatus 730.

The first switch 720h may be a metal oxide semiconductor field effect transistor (MOSFET). Alternatively, the first switch 720h may also be other components that turn on or off when triggered by a level signal.

In the implementation of the present disclosure, a GPIO interface circuit and a switch may be provided in the testing adapter 720 to control the power on/off of the memory apparatus 730 during the testing process of the memory apparatus. In an example implementation, as shown in FIG. 11, when a tester needs to control the power on/off of the memory apparatus 730, a power on/off instruction (e.g., the third control instruction mentioned above in USB protocol format) may be sent to the first interface circuit 720a in the testing adapter 720 by the host 710. The first bridge chip 720e1 receives the power on/off instruction (in USB protocol format) from the first interface circuit 720a, identifies the instruction type/content of the power on/off instruction, determines that the power on/off instruction is an instruction to control the memory apparatus 730 to power on or off, and sends a trigger signal to the first GPIO interface circuit 720g after generating the corresponding trigger signal from the power on/off instruction (the trigger signal is used to trigger the first GPIO interface circuit 720g to generate a corresponding level signal). The first GPIO interface circuit 720g generates a first level signal from the trigger signal and sends the first level signal to the first switch 720h, and the first switch 720h is disconnected or connected under the trigger of the first level signal.

For example, in an example in which the first switch 720h is on at a low level and off at a high level, when a tester needs to control the memory apparatus 730 to power on, a power on instruction may be sent to the first interface circuit 720a by the host 710. The first bridge chip 720e1 receives the power on instruction from the first interface circuit 720a, generates a trigger signal to power on, and sends the trigger signal to the first GPIO interface circuit 720g. The first GPIO interface circuit 720g generates a low-level signal from the trigger signal and sends the low-level signal to the first switch 720h. The first switch 720h is connected (or turned on) under the triggering of the low-level signal, so as to achieve the power on of the memory apparatus 730. Correspondingly, when the tester needs to control the power off of the memory apparatus 730, a power off instruction may be sent to the first interface circuit 720a by the host 710. The first bridge chip 720e1 receives the power off instruction from the first interface circuit 720a, generates a trigger signal to power off, and sends the trigger signal to the first GPIO interface circuit 720g. The first GPIO interface circuit 720g generates a high-level signal from the trigger signal and sends the high-level signal to the first switch 720h. The first switch 720h is disconnected under the triggering of the high-level signal, so as to achieve the power off of the memory apparatus 730.

In the implementation of the present disclosure, a first GPIO interface circuit 720g and a first switch 720h are built into the testing adapter, and a bridge chip is configured to trigger the first GPIO interface circuit 720g based on the power on/off signal set by the host 710 to send a level signal to the first switch 720h, so as to accurately and quickly control the power on/off of the memory apparatus 730, simplify the complexity of the power on/off control process of the memory apparatus, and ensure the execution efficiency and flexibility of the power on/off control in the testing process.

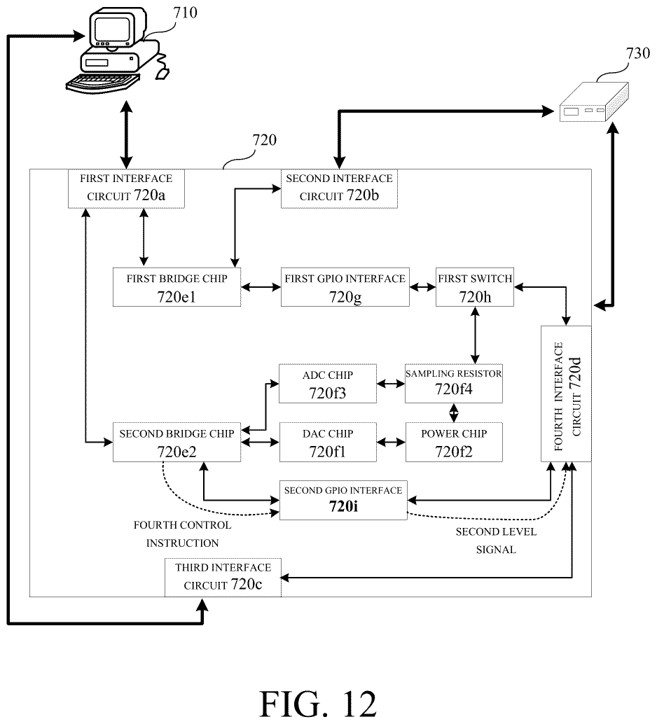

Based on the aspects illustrated in any one or more of the above implementations, in some implementations, please refer to FIG. 12, which illustrates a structural diagram of a testing adapter involved in an implementation of the present disclosure. As shown in FIG. 12, the testing adapter 720 further includes a second GPIO interface circuit 720i. The second GPIO interface circuit 720i is configured to be connected to a second target chip, and be connected to the fourth interface circuit 720d. The second target chip may be one of the first bridge chip 720e1 and the second bridge chip 720e2, and as shown in FIG. 12, the second target chip is the second bridge chip 720e2. The second target chip is configured to receive from the first interface circuit 720a a fourth control instruction from the host 710, and trigger the second GPIO interface circuit 720i based on the fourth control instruction to send a second level signal to the memory apparatus 730 through the fourth interface circuit 720d.

The second level signal mentioned above may include, but is not limited to a PCIe Sideband signal. In some implementations, the PCIe Sideband signal is to implement PCIe Sideband control functionality during testing of the memory apparatus 730.

In an example implementation, as shown in FIG. 12, when a tester needs to control the execution of PCIe Sideband control, a PCIe Sideband control instruction (e.g., the fourth control instruction mentioned above in USB protocol format) may be sent to the first interface circuit 720a in the testing adapter 720 by the host 710. The second bridge chip 720e2 receives the PCIe Sideband control instruction (in USB protocol format) from the first interface circuit 720a, identifies the instruction type/content of the PCIe Sideband control instruction, determines that it is an instruction to execute PCIe Sideband control, generates a corresponding level signal (e.g., the second level signal mentioned above) based on the PCIe Sideband control instruction, and sends the level signal to the fourth interface circuit 720d to achieve PCIe Sideband control.

In the implementation of the present disclosure, a second GPIO interface circuit 720i is built into the testing adapter, and a bridge chip is configured to trigger a level signal corresponding to the PCIe Sideband control function based on the PCIe Sideband control signal set by the host 710, so as to accurately and quickly trigger the PCIe Sideband control function, simplify the complexity of implementing the PCIe Sideband control function, and ensure the execution efficiency and flexibility of the PCIe Sideband control function during the testing process.

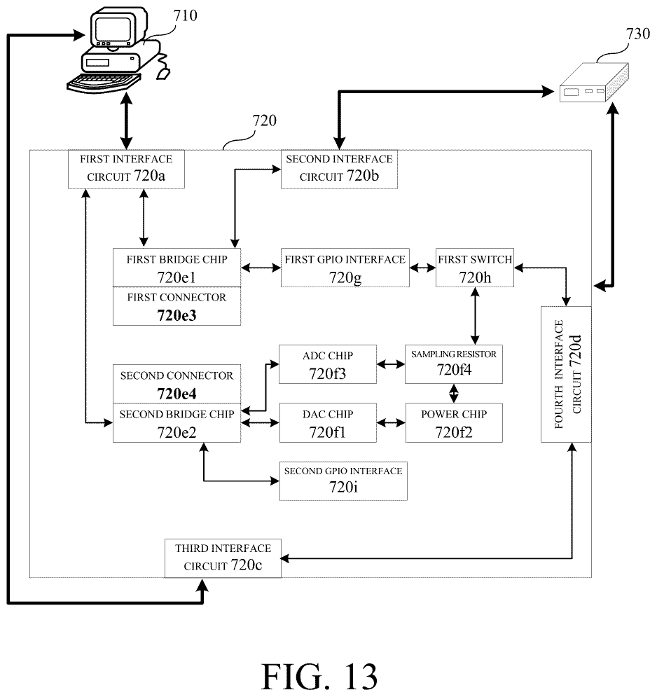

Based on the aspects illustrated in any one or more of the above implementations, in some implementations, please refer to FIG. 13, which illustrates a structural diagram of a testing adapter involved in an implementation of the present disclosure. As shown in FIG. 13, the first bridge chip 720e1 has a first connector 720e3, and the first connector 720e3 is configured to be connected to a programming device, so that the programming device may rewrite the firmware of the first bridge chip 720e1 through the first connector 720e3; and/or the second bridge chip 720e2 has a second connector 720e4, and the second connector 720e4 is configured to be connected to a programming device, so that the programming device may rewrite the firmware of the second bridge chip 720e2 through the second connector 720e4.

In the implementation of the present disclosure, the bridge chip in the testing adapter 720 may reserve a connector for an external connection. When a tester needs to expand or modify the function of the testing adapter 720, the connector of the bridge chip may be connected with a programming device, and the firmware of the bridge chip may be rewritten by the programming device, so as to flexibly expand the functions of the testing adapter 720 and improve its scalability.

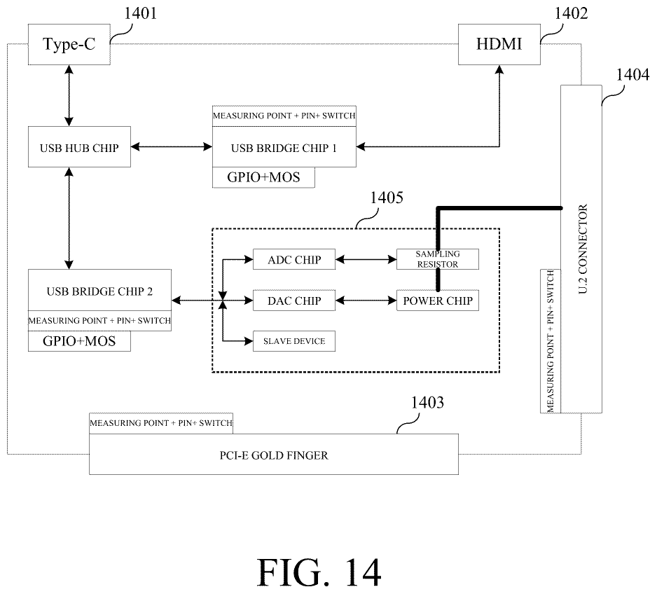

Based on the aspects illustrated in any one or more of the above implementations, in some implementations, please refer to FIG. 14, which illustrates a structural diagram of a testing adapter involved in an implementation of the present disclosure. As shown in FIG. 14, for an external connection, the testing adapter includes a Type-C interface 1401 (corresponding to the first interface circuit 720a), an HDMI interface 1402 (corresponding to the second interface circuit 720b), a PCI-E gold finger 1403 (corresponding to the third interface circuit 720c), and a U.2 connector 1404 (corresponding to the fourth interface circuit 720d). The USB bridge chip 1 (corresponding to the first bridge chip 720e1), USB bridge chip 2 (corresponding to the second bridge chip 720e2), and SMBus slave device 1405 (corresponding to one or more SMBus slave devices 720f) are included in the testing adapter. The USB bridge chip 1 and USB bridge chip 2 are respectively connected to Type-C interface 1401 through a USB HUB chip, and USB bridge chip 1 is connected to the HDMI interface 1402. SMBus slave device 1405 includes an ADC chip (corresponding to ADC chip 720f3), a sampling resistor (corresponding to sampling resistor 720f4), a DAC chip (corresponding to DAC chip 720f1), and a power chip (corresponding to power chip 720f2). In an example, SMBus slave device 1405 may further include other slave devices. The USB bridge chip 1 and USB bridge chip 2 are respectively connected with a GPIO circuit (not limited to the first GPIO interface circuit 720g and the second GPIO interface circuit 720i) and/or MOS (not limited to the first switch 720h). In addition, the USB bridge chip 1 and USB bridge chip 2 are respectively configured with a connector (not limited to the first connector 720e3 and the second connector 720e4) comprising a measuring point, a PIN, and a switch circuit. In FIG. 14, the line indicated by a double arrow is a signal transmission line, and the bolded line is a power transmission line.

The testing adapter shown in FIG. 14 has the advantages as below.
1) Circuits or components required to achieve multiple different testing functions are integrated in a testing adapter. In an example, by using an AIC-U2 adapter card as a carrier, functional circuits such as UART, JTAG, power on/off, voltage bias, and current sampling, etc. are integrated.
2) instead of MCU or CPU, two USB bridge chips are used to complete the aforementioned testing functions.
3) By reasonably scheduling printed circuit board (PCB) resources and reserving dip switches and connector points (corresponding to the first connector 720e3 and the second connector 720e4), hardware allows testers to conduct a secondary development according to their own needs.

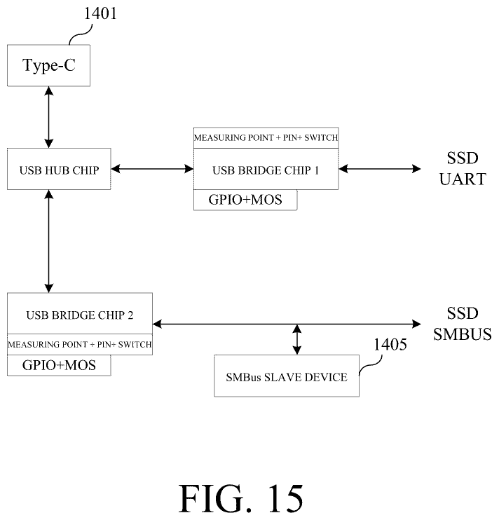

Please refer to FIG. 15, which shows a schematic diagram of a partial structure of a testing adapter involved in an implementation of the present disclosure. As shown in FIG. 15, in the aspect illustrated in the implementation of the present disclosure, a Type-C interface is configured to connect with a control PC (e.g., the aforementioned host 710), and a path is split into two paths by a USB hub, which are respectively connected to two bridge chips. The USB bridge chip 1 may convert a UART signal of SSD into a USB signal to manage the Debug information of SSD. At the same time, the USB bridge chip 2 may convert a USB signal into a SMBus signal for NVMe-MI testing related to PCIe, achieving voltage bias, sampling, or other functions. In addition, both USB bridge chip 1 and USB bridge chip 2 have their own extended IO. A tester may modify the driver code to achieve various IO configurations and basic controls. Functions such as SSD power off and PCIe Sideband control are also achieved by GPIO.

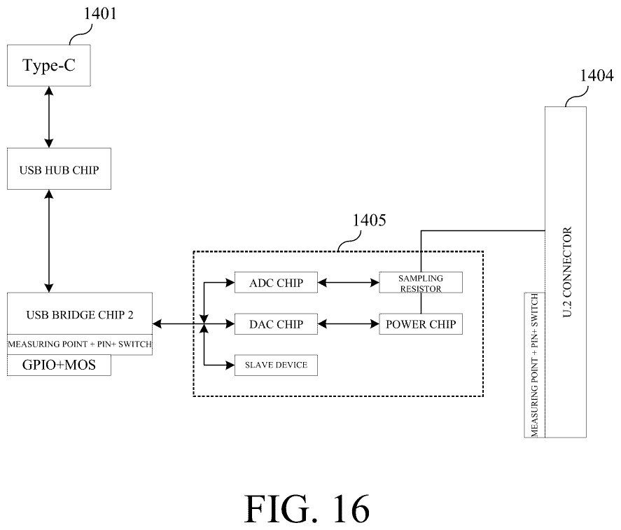

Please refer to FIG. 16, which shows a schematic diagram of a partial structure of a testing adapter involved in an implementation of the present disclosure. As shown in FIG. 16, FIG. 16 illustrates a structure in the testing adapter that implements voltage bias, voltage and current sampling functions. The voltage bias, voltage and current sampling functions are achieved by issuing an instruction by USB and converting the instruction into a SMBus signal by the USB bridge chip 2 to control the DAC chip and ADC chip, based on the development of a driver of the USB bridge chip 2 at a software level.
1) Voltage bias function: an output of the DAC chip is connected to the feedback (FB) pin of a power chip (such as a Buck-Boost chip), and the host may linearly adjust the output of the Buck-Boost power supply by controlling the output of the DAC chip by means of USB bridge chip 2.
2) Voltage and current sampling function: the voltage values across the sampling resistor are transmitted to the ADC chip, and the USB bridge chip 2 reads out the analog voltage value through SMBus and transmits a converted digital voltage and current value to the host.

Based on the structures shown in FIGS. 14 to 16 above, taking four testing functions: power off control, bias voltage control initialization, bias voltage control, and voltage sampling as an example, the software implementation process for testing an SSD based on the test adapter as described above will be introduced.

### 1. Implementation Process of Power On/Off Control

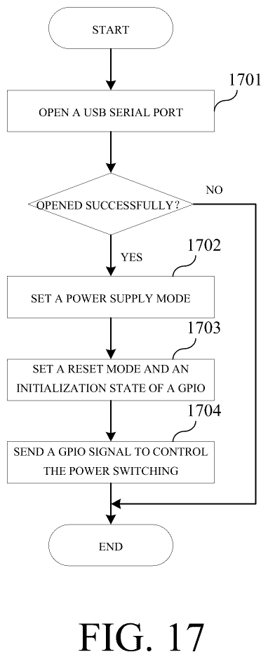

Please refer to FIG. 17, which illustrates a schematic diagram of an implementation process of power on/off control involved in an implementation of the present disclosure. As shown in FIG. 17, the power on/off control process requires determining a value of a GPIO signal based on the hardware connection approach, and implementing power on/off of SSD by sending the GPIO signal. In an example, the testing software in the host needs to determine a serial port number for power off control and open the corresponding USB serial port (operation 1701). If the USB serial port is occupied, it will result in the open failure. If the USB serial port is opened successfully, the testing software first sets a power supply mode corresponding to the SSD (operation 1702), and then configures a reset mode and a level initialization state of the used GPIO (operation 1703). A correct chip configuration is the basis for the power on/off control. Next, the GPIO values for the power on state and power off state will be calculated, respectively, based on the GPIO configuration, and the operating system will call a function to send an I/O signal (e.g., a GPIO signal, including the corresponding GPIO value for the power on state or power off state, the GPIO signal corresponding to the third control instruction mentioned above) to the driver to control the power switching (operation 1704). The driver will send a power on/off signal to the testing adapter to achieve the power on/off of the testing adapter and SSD.

### 2. Implementation Process of Bias Voltage Control Initialization

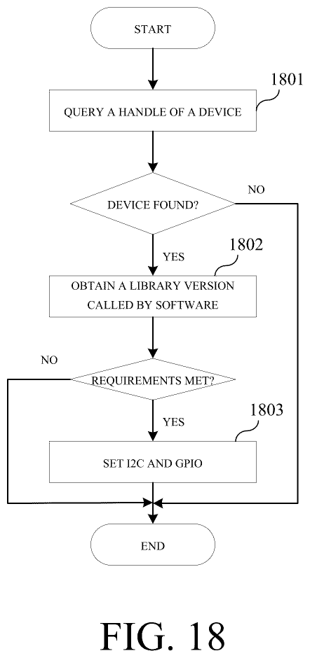

Please refer to FIG. 18, which illustrates a schematic diagram of an implementation process of bias voltage control involved in an implementation of the present disclosure. As shown in FIG. 18, the initialization process of bias voltage control mainly carries out an initialization of a chip. Firstly, a testing software queries a handle of a device (operation 1801) to obtain an operation handle of the device, which may be a testing adapter or a chip/circuit related to bias voltage control in the testing adapter. For example, the testing software searches for the required device from the system based on the VID (supplier ID) and PID (product ID) of the chip related to bias voltage control. If the required device does not exist, it is determined that the chip cannot be found, and a direct exit operation is performed. If the chip is found, it is determined that the device has been found. At this time, the library version called by the software may be obtained (operation 1802), and the version may be checked to see if it meets the requirements. When the requirements are met, an inter-integrated circuit (I2C) function and GPIO status of the chip will be configured (operation 1803) to initialize the chip.

### 3. Implementation Process of Bias Voltage Control

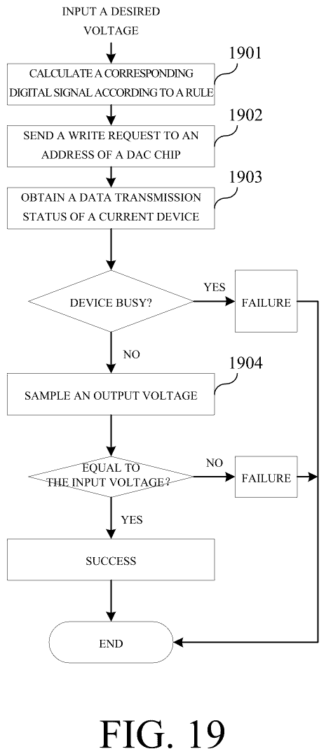

Please refer to FIG. 19, which illustrates a schematic diagram of an implementation process of bias voltage control involved in an implementation of the present disclosure. As shown in FIG. 19, the implementation process of bias voltage control mainly includes: controlling, by a bridge chip, a DAC chip of a slave device to achieve an output of a bias voltage, and controlling an ADC chip of the slave device to achieve the sampling of the output bias voltage, in order to confirm whether a desired bias voltage is achieved through the sampling results.

For example, when a tester inputs a desired analog voltage value, the testing software first calculates a digital signal corresponding to the input analog voltage value according to a design rule (operation 1901), and then sends a write request to the address of the ADC chip of the slave device (operation 1902), with a digital signal value written into the device together, After a successful writing, a data transmission status of the current device (e.g., the testing adapter mentioned above) is obtained (operation 1903), and it is determined from the obtained result that whether the current device is busy. If it is busy, the current command has failed. If it is idle, the output voltage may be sampled (operation 1904), and the sampling result may be checked to see if it is consistent with the input voltage. If it is consistent, the voltage setting is successful, and the entire closed-loop operation is completed. This approach provides a voltage sampling process to facilitate a user to determine whether the voltage has been set successfully and to facilitate the implementation of an automated testing process.

### 4. Implementation Process of Voltage Sampling

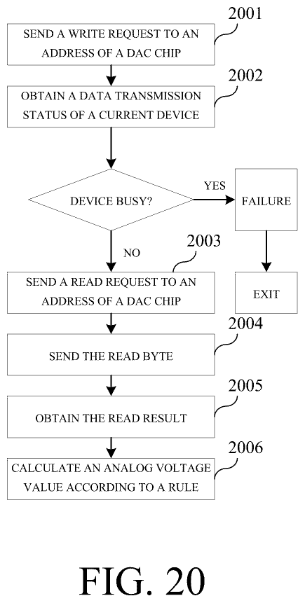

Please refer to FIG. 20, which illustrates a schematic diagram of an implementation process of bias voltage control involved in an implementation of the present disclosure. As shown in FIG. 20, after a user sets a bias voltage successfully, a voltage sampling process is entered. Firstly, a testing software sends a write request to the address of the ADC chip of a slave device (operation 2001), notifying the ADC chip to prepare data for a specific address. After a successful writing, a data transmission status of the current device is obtained (operation 2002), and it is determined from the obtained result that whether the current device is busy. If it is busy, the current command has failed, and if it is idle, a further operation may be carried out, that is, a read request may be sent to the address of the ADC chip of the slave device (operation 2003), and the read byte is sent (operation 2004). Finally, the read result is obtained (operation 2005), an analog voltage value corresponding to the currently obtained result is calculated according to a design rule (operation 2006), and a next operation is carried out to check the consistency between the sampled result and the input voltage.

An example implementation of the present disclosure further provides a testing system for a memory apparatus. The testing system comprises a testing adapter and a host, wherein the testing adapter comprises a first interface circuit, a second interface circuit, a third interface circuit, a fourth interface circuit, a first bridge chip, and a second bridge chip; the first interface circuit and the third interface circuit are configured to be connected to the host, respectively, the second interface circuit is configured to be connected to a debugging information interface circuit of the memory apparatus, and the fourth interface circuit is configured to be connected to a data interface circuit of the memory apparatus; the first bridge chip is configured to be connected to the first interface circuit, and be connected to the second interface circuit, and the second bridge chip is configured to be connected to the first interface circuit, and be connected to the fourth interface circuit; the host is configured to send a testing control instruction to the testing adapter; and the testing adapter is configured so that the first bridge chip and the second bridge chip perform a testing operation on the memory apparatus based on the testing control instruction.

The structures shown in FIGS. 7 to 16 may be referred for the connection between the host and the testing adapter, the connection between the testing adapter and the memory apparatus, and the internal structure of the testing adapter.

Based on the aspects illustrated in any one or more of the above implementations, in some implementations, the testing adapter further comprises at least one system management bus slave device; and the second bridge chip is configured to be connected to the at least one system management bus slave device, and the at least one system management bus slave device is configured to be connected to the fourth interface circuit.

Based on the aspects illustrated in any one or more of the above implementations, in some implementations, the testing adapter is configured so that the first bridge chip receives from the first interface circuit a first control instruction from the host, and sends the first control instruction to the memory apparatus through the second interface circuit after converting a format of the first control instruction into a format of a protocol corresponding to the second interface circuit, and the first control instruction instructs the memory apparatus to perform a first testing-related operation; and the testing adapter is configured so that the first bridge chip receives from the second interface circuit debugging information sent by the memory apparatus, and sends the debugging information to the host through the first interface circuit after converting a format of the debugging information into a format of a protocol corresponding to the first interface circuit.

Based on the aspects illustrated in any one or more of the above implementations, in some implementations, the first control instruction comprises at least one of: an instruction to perform Universal Asynchronous Receiver/Transmitter (UART) testing; an instruction to perform Joint Test Action Group (JTAG) testing; and an instruction to perform Non-volatile Memory Expansion Management Interface (NVMe-MI) circuit testing related to Peripheral Component Interconnect Extension (PCI-E).

Based on the aspects illustrated in any one or more of the above implementations, in some implementations, the testing adapter is configured so that the second bridge receives from the first interface circuit a second control instruction from the host, and sends the second control instruction to a target slave device chip after converting a format of the second control instruction into a format of a system management bus protocol, and the target slave device is one or more of the at least one system management bus slave device; and the testing adapter is configured so that the target slave device performs a second testing-related operation based on the second control instruction.

Based on the aspects illustrated in any one or more of the above implementations, in some implementations, the at least one system management bus slave device comprises a digital-to-analog conversion (DAC) chip and a power chip; the second bridge chip is configured to be connected to the DAC chip, the DAC chip is configured to be connected to the power chip, and the power chip is configured to be connected to the fourth interface circuit; in the case where the second control instruction includes a bias voltage control instruction, the testing adapter is configured so that the second bridge chip sends the bias voltage control instruction to the DAC chip after converting a format of the bias voltage control instruction into a format of the system management bus protocol; the testing adapter is configured so that the DAC chip sends an analog voltage signal to the power chip after converting a digital voltage signal corresponding to the bias voltage control instruction into the analog voltage signal; and the testing adapter is configured so that the power chip controls a voltage output to the fourth interface circuit based on the analog voltage signal.

Based on the aspects illustrated in any one or more of the above implementations, in some implementations, the at least one system management bus slave device further comprises an analog-to-digital conversion (ADC) chip and a sampling resistor; the second bridge chip is configured to be connected to the ADC chip, the ADC chip is configured to be connected to the sampling resistor, and the sampling resistor is in a circuit between the power chip and the fourth interface circuit; in the case where the second control instruction includes a sampling instruction, the testing adapter is configured so that the second bridge chip sends the sampling instruction to the ADC chip after converting a format of the sampling instruction into a format of the system management bus protocol; the testing adapter is configured so that the ADC chip samples at least one of a voltage and a current of the sampling resistor to obtain a sampled analog signal, converts the sampled analog signal into a sampled digital signal, and sends the sampled digital signal to the second bridge chip based on the sampling instruction; and the testing adapter is further configured so that the second bridge chip sends the sampled digital signal to the host through the first interface circuit after converting a format of the sampled digital signal into a format of a protocol corresponding to the first interface circuit.

Based on the aspects illustrated in any one or more of the above implementations, in some implementations, the testing adapter further comprises a first general-purpose input/output (GPIO) interface circuit and a first switch; the first GPIO interface circuit is configured to be connected to a first target chip and be connected to the first switch, the first switch is in a power supply circuit of the testing adapter for supplying power to the memory apparatus, and the first target chip is one of the first bridge chip and the second bridge chip; and the testing adapter is configured so that the first target chip receives from the first interface circuit a third control instruction from the host, and triggers the first GPIO interface circuit to send a first level signal to the first switch based on the third control instruction, wherein the first level signal is configured to trigger the first switch to disconnect or connect to control power on/off of the memory apparatus.

Based on the aspects illustrated in any one or more of the above implementations, in some implementations, the testing adapter further comprises a second GPIO interface circuit; the second GPIO interface circuit is configured to be connected to a second target chip and be connected to the fourth interface circuit, and the second target chip is one of the first bridge chip and the second bridge chip; and the testing adapter is configured so that the second target chip receives from the first interface circuit a fourth control instruction from the host, and triggers the second GPIO interface circuit to send a second level signal to the memory apparatus through the fourth interface circuit based on the fourth control instruction.

Based on the aspects illustrated in any one or more of the above implementations, in some implementations, the first bridge chip has a first connector, and the first connector is configured to be connected to a programming device, so that the programming device rewrites a firmware of the first bridge chip through the first connector; and/or the second bridge chip has a second connector, and the second connector is configured to be connected to a programming device, so that the programming device rewrites a firmware of the second bridge chip through the second connector.

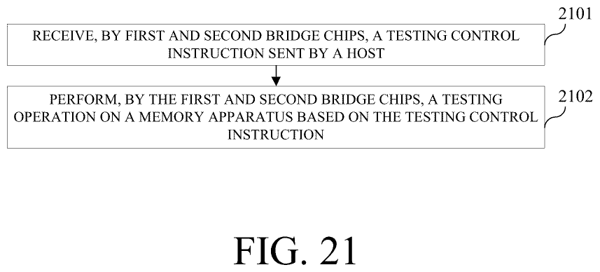

FIG. 21 shows a flowchart of a testing method for a memory apparatus provided by an example implementation of the present disclosure. The method is performed by a testing adapter. The testing adapter includes a first interface circuit, a second interface circuit, a third interface circuit, a fourth interface circuit, a first bridge chip, and a second bridge chip. The first interface circuit and the third interface circuit are configured to be connected to a host, respectively. The second interface circuit is configured to be connected to a debugging information interface circuit of the memory apparatus. The fourth interface circuit is configured to be connected to a data interface circuit of the memory apparatus. The first bridge chip is configured to be connected to the first interface circuit, and be connected to the second interface circuit. The second bridge chip is configured to be connected to the first interface circuit, and be connected to the fourth interface circuit. The structures shown in FIGS. 7 to 16 may be referred for the connection between the host and the testing adapter, the connection between the testing adapter and the memory apparatus, and the internal structure of the testing adapter. As shown in FIG. 21, the method may include operations 2101 and 2102.

At operation 2101, the first bridge chip and the second bridge chip receive a testing control instruction sent by a host.

At operation 2102, the first bridge chip and the second bridge chip perform a testing operation on the memory apparatus based on the testing control instruction.

Based on the aspects illustrated in any one or more of the above implementations, in some implementations, the testing adapter further comprises at least one system management bus slave device; and the second bridge chip is connected to the at least one system management bus slave device, and the at least one system management bus slave device is connected to the fourth interface circuit.

Based on the aspects illustrated in any one or more of the above implementations, in some implementations, the receiving, by the first bridge chip and the second bridge chip, the testing control instruction sent by the host comprises: the first bridge chip receiving from the first interface circuit a first control instruction from the host, and sending the first control instruction to the memory apparatus through the second interface circuit after converting a format of the first control instruction into a format of a protocol corresponding to the second interface circuit, wherein the first control instruction instructs the memory apparatus to perform a first testing-related operation; and the first bridge chip receiving from the second interface circuit debugging information sent by the memory apparatus, and sending the debugging information to the host through the first interface circuit after converting a format of the debugging information into a format of a protocol corresponding to the first interface circuit.

Based on the aspects illustrated in any one or more of the above implementations, in some implementations, the first control instruction includes at least one of: an instruction to perform Universal Asynchronous Receiver/Transmitter (UART) testing; an instruction to perform Joint Test Action Group (JTAG) testing; and an instruction to perform Non-volatile Memory Expansion Management Interface (NVMe-MI) circuit testing related to Peripheral Component Interconnect Extension (PCI-E).

Based on the aspects illustrated in any one or more of the above implementations, in some implementations, the receiving, by the first bridge chip and the second bridge chip, the testing control instruction sent by the host comprises: the second bridge chip receiving from the first interface circuit a second control instruction from the host, and sending the second control instruction to a target slave device after converting a format of the second control instruction into a format of the system management bus protocol, wherein the target slave device is one or more of the at least one system management bus slave device; and the target slave device performing a second testing-related operation based on the second control instruction.

Based on the aspects illustrated in any one or more of the above implementations, in some implementations, the at least one system management bus slave device comprises a digital-to-analog conversion (DAC) chip and a power chip; the second bridge chip is configured to be connected to the DAC chip, the DAC chip is configured to be connected to the power chip, and the power chip is configured to be connected to the fourth interface circuit; the sending the second control instruction to the target slave device after converting the format of the second control instruction into the format of the system management bus protocol comprises: in the case where the second control instruction includes a bias voltage control instruction, the second bridge chip sending the bias voltage control instruction to the DAC chip after converting a format of the bias voltage control instruction into a format of the system management bus protocol; and the target slave device performing the second testing-related operation based on the second control instruction comprises: the DAC chip sending an analog voltage signal to the power chip after converting a digital voltage signal corresponding to the bias voltage control instruction into the analog voltage signal; and the power chip controlling a voltage output to the fourth interface circuit based on the analog voltage signal.

Based on the aspects illustrated in any one or more of the above implementations, in some implementations, the at least one system management bus slave device further comprises an analog-to-digital conversion (ADC) chip and a sampling resistor; the second bridge chip is configured to be connected to the ADC chip, the ADC chip is configured to be connected to the sampling resistor, and the sampling resistor is in a circuit between the power chip and the fourth interface circuit; the sending the second control instruction to the target slave device after converting the format of the second control instruction into the format of the system management bus protocol comprises: in the case where the second control instruction includes a sampling instruction, the second bridge chip sending the sampling instruction to the ADC chip after converting a format of the sampling instruction into a format of the system management bus protocol; the target slave device performing the second testing-related operation based on the second control instruction comprises: the ADC chip sampling at least one of a voltage and a current of the sampling resistor to obtain a sampled analog signal, converting the sampled analog signal into a sampled digital signal, and sending the sampled digital signal to the second bridge chip based on the sampling instruction; and the method further comprises: sending, by the second bridge chip, the sampled digital signal to the host through the first interface circuit after converting a format of the sampled digital signal into a format of a protocol corresponding to the first interface circuit.

Based on the aspects illustrated in any one or more of the above implementations, in some implementations, the testing adapter further comprises a first general-purpose input/output (GPIO) interface circuit and a first switch; the first GPIO interface circuit is configured to be connected to a first target chip and be connected to the first switch, the first switch is in a power supply circuit of the testing adapter for supplying power to the memory apparatus, and the first target chip is one of the first bridge chip and the second bridge chip; the receiving, by the first bridge chip and the second bridge chip, the testing control instruction sent by the host comprises: the first target chip receiving from the first interface circuit a third control instruction from the host; and the performing, by the first bridge chip and the second bridge chip, the testing operation on the memory apparatus based on the testing control instruction comprises: the first target chip triggering the first GPIO interface circuit to send a first level signal to the first switch based on the third control instruction, wherein the first level signal is configured to trigger the first switch to disconnect or connect to control the power on/off of the memory apparatus.

Based on the aspects illustrated in any one or more of the above implementations, in some implementations, the testing adapter further comprises a second GPIO interface circuit; the second GPIO interface circuit is configured to be connected to a second target chip and be connected to the fourth interface circuit, and the second target chip is one of the first bridge chip and the second bridge chip; the receiving, by the first bridge chip and the second bridge chip, the testing control instruction sent by the host comprises: the second target chip receiving from the first interface circuit a fourth control instruction from the host; and the performing, by the first bridge chip and the second bridge chip, the testing operation on the memory apparatus based on the testing control instruction comprises: the second target chip triggering the second GPIO interface circuit to send a second level signal to the memory apparatus through the fourth interface circuit based on the fourth control instruction.

In this disclosure, terms “first” and “second” are only used for descriptive purposes and should not be construed as indicating or implying relative importance. The term “at least one of” refers to one or more, and the term “multiple” refers to two or more, unless otherwise specified. The term “and/or” in the present disclosure is only a description of the association relationship between related objects, indicating that there may be three types of relationships. For example, A and/or B may represent A alone, both A and B, and B alone. In addition, the character “/” herein generally indicates that the related objects before and after are in an “or” relationship.

The present disclosure provides a testing adapter, a testing system, and a testing method for a memory apparatus, which may simplify the complexity of testing the memory apparatus and improve the efficiency of testing the memory apparatus. The example technical aspects of the present disclosure are as follows.

In a first aspect, a testing adapter for a memory apparatus is provided. The testing adapter comprises a first interface circuit, a second interface circuit, a third interface circuit, a fourth interface circuit, a first bridge chip, and a second bridge chip, wherein the first interface circuit and the third interface circuit are configured to be connected to a host, respectively, the second interface circuit is configured to be connected to a debugging information interface circuit of the memory apparatus, and the fourth interface circuit is configured to be connected to a data interface circuit of the memory apparatus; the first bridge chip is configured to be connected to the first interface circuit and be connected to the second interface circuit, and the second bridge chip is configured to be connected to the first interface circuit and be connected to the fourth interface circuit; and the first bridge chip and the second bridge chip are configured to perform a testing operation on the memory apparatus based on a testing control instruction sent by the host.

In an example implementation, the testing adapter further comprises at least one system management bus slave device, wherein the second bridge chip is configured to be connected to the at least one system management bus slave device, and the at least one system management bus slave device is configured to be connected to the fourth interface circuit.

In an example implementation, the first bridge chip is configured to receive from the first interface circuit a first control instruction from the host, and send the first control instruction to the memory apparatus through the second interface circuit after converting a format of the first control instruction into a format of a protocol corresponding to the second interface circuit, and the first control instruction instructs the memory apparatus to perform a first testing-related operation; and the first bridge chip is configured to receive from the second interface circuit debugging information sent by the memory apparatus, and send the debugging information to the host through the first interface circuit after converting a format of the debugging information into a format of a protocol corresponding to the first interface circuit.

In an example implementation, the first control instruction comprises at least one of: an instruction to perform Universal Asynchronous Receiver/Transmitter (UART) testing; an instruction to perform Joint Test Action Group (JTAG) testing; and an instruction to perform Non-volatile Memory Expansion Management Interface (NVMe-MI) circuit testing related to Peripheral Component Interconnect Extension (PCI-E).

In an example implementation, the second bridge chip is configured to receive from the first interface circuit a second control instruction from the host, and send the second control instruction to a target slave device after converting a format of the second control instruction into a format of a system management bus protocol, wherein the target slave device is one or more of the at least one system management bus slave device; and the target slave device is configured to perform a second testing-related operation based on the second control instruction.

In an example implementation, the at least one system management bus slave device comprises a digital-to-analog conversion (DAC) chip and a power chip; the second bridge chip is configured to be connected to the DAC chip, the DAC chip is configured to be connected to the power chip, and the power chip is configured to be connected to the fourth interface circuit; in the case where the second control instruction includes a bias voltage control instruction, the second bridge chip is configured to send the bias voltage control instruction to the DAC chip after converting a format of the bias voltage control instruction into a format of the system management bus protocol; the DAC chip is configured to send an analog voltage signal to the power chip after converting a digital voltage signal corresponding to the bias voltage control instruction into the analog voltage signal; and the power chip is configured to control a voltage output to the fourth interface circuit based on the analog voltage signal.

In an example implementation, the at least one system management bus slave device further comprises an analog-to-digital conversion (ADC) chip and a sampling resistor; the second bridge chip is configured to be connected to the ADC chip, the ADC chip is configured to be connected to the sampling resistor, and the sampling resistor is in a circuit between the power chip and the fourth interface circuit; in the case where the second control instruction includes a sampling instruction, the second bridge chip is configured to send the sampling instruction to the ADC chip after converting a format of the sampling instruction into a format of the system management bus protocol; the ADC chip is configured to sample at least one of a voltage and a current of the sampling resistor to obtain a sampled analog signal, convert the sampled analog signal into a sampled digital signal, and send the sampled digital signal to the second bridge chip based on the sampling instruction; and the second bridge chip is further configured to send the sampled digital signal to the host through the first interface circuit after converting a format of the sampled digital signal into a format of a protocol corresponding to the first interface circuit.

In an example implementation, the testing adapter further comprises a first general-purpose input/output (GPIO) interface circuit and a first switch, wherein the first GPIO interface circuit is configured to be connected to a first target chip and be connected to the first switch, the first switch is in a power supply circuit of the testing adapter for supplying power to the memory apparatus, and the first target chip is one of the first bridge chip and the second bridge chip; and the first target chip is configured to receive from the first interface circuit a third control instruction from the host, and trigger the first GPIO interface circuit to send a first level signal to the first switch based on the third control instruction, wherein the first level signal is configured to trigger the first switch to disconnect or connect to control power on/off of the memory apparatus.

In an example implementation, the testing adapter further comprises a second GPIO interface circuit, wherein the second GPIO interface circuit is configured to be connected to a second target chip and be connected to the fourth interface circuit, and the second target chip is one of the first bridge chip and the second bridge chip; and the second target chip is configured to receive from the first interface circuit a fourth control instruction from the host, and trigger the second GPIO interface circuit to send a second level signal to the memory apparatus through the fourth interface circuit based on the fourth control instruction.

In an example implementation, the first bridge chip has a first connector, and the first connector is configured to be connected to a programming device, so that the programming device rewrites a firmware of the first bridge chip through the first connector; and/or the second bridge chip has a second connector, and the second connector is configured to be connected to a programming device, so that the programming device rewrites a firmware of the second bridge chip through the second connector.

In a second aspect, a testing system for a memory apparatus is provided. The testing system comprises a testing adapter and a host, wherein the testing adapter comprises a first interface circuit, a second interface circuit, a third interface circuit, a fourth interface circuit, a first bridge chip, and a second bridge chip; the first interface circuit and the third interface circuit are configured to be connected to the host, respectively, the second interface circuit is configured to be connected to a debugging information interface circuit of the memory apparatus, and the fourth interface circuit is configured to be connected to a data interface circuit of the memory apparatus; the first bridge chip is configured to be connected to the first interface circuit and be connected to the second interface circuit, and the second bridge chip is configured to be connected to the first interface circuit and be connected to the fourth interface circuit; the host is configured to send a testing control instruction to the testing adapter; and the testing adapter is configured so that the first bridge chip and the second bridge chip perform a testing operation on the memory apparatus based on the testing control instruction.

In an example implementation, the testing adapter further comprises at least one system management bus slave device; and the second bridge chip is configured to be connected to the at least one system management bus slave device, and the at least one system management bus slave device is configured to be connected to the fourth interface circuit.

In an example implementation, the testing adapter is configured so that the first bridge chip receives from the first interface circuit a first control instruction from the host, and sends the first control instruction to the memory apparatus through the second interface circuit after converting a format of the first control instruction into a format of a protocol corresponding to the second interface circuit, and the first control instruction instructs the memory apparatus to perform a first testing-related operation; and the testing adapter is configured so that the first bridge chip receives from the second interface circuit debugging information sent by the memory apparatus, and sends the debugging information to the host through the first interface circuit after converting a format of the debugging information into a format of a protocol corresponding to the first interface circuit.

In an example implementation, the first control instruction comprises at least one of: an instruction to perform Universal Asynchronous Receiver/Transmitter (UART) testing; an instruction to perform Joint Test Action Group (JTAG) testing; and an instruction to perform Non-volatile Memory Expansion Management Interface (NVMe-MI) circuit testing related to Peripheral Component Interconnect Extension (PCI-E).

In an example implementation, the testing adapter is configured so that the second bridge chip receives from the first interface circuit a second control instruction from the host, and sends the second control instruction to a target slave device after converting a format of the second control instruction into a format of a system management bus protocol, and the target slave device is one or more of the at least one system management bus slave device; and the testing adapter is configured so that the target slave device performs a second testing-related operation based on the second control instruction.

In an example implementation, the at least one system management bus slave device comprises a digital-to-analog conversion (DAC) chip and a power chip; the second bridge chip is configured to be connected to the DAC chip, the DAC chip is configured to be connected to the power chip, and the power chip is configured to be connected to the fourth interface circuit; in the case where the second control instruction includes a bias voltage control instruction, the testing adapter is configured so that the second bridge chip sends the bias voltage control instruction to the DAC chip after converting a format of the bias voltage control instruction into a format of the system management bus protocol; the testing adapter is configured so that the DAC chip sends an analog voltage signal to the power chip after converting a digital voltage signal corresponding to the bias voltage control instruction into the analog voltage signal; and the testing adapter is configured so that the power chip controls a voltage output to the fourth interface circuit based on the analog voltage signal.

In an example implementation, the at least one system management bus slave device further comprises an analog-to-digital conversion (ADC) chip and a sampling resistor; the second bridge chip is configured to be connected to the ADC chip, the ADC chip is configured to be connected to the sampling resistor, and the sampling resistor is in a circuit between the power chip and the fourth interface circuit; in the case where the second control instruction includes a sampling instruction, the testing adapter is configured so that the second bridge chip sends the sampling instruction to the ADC chip after converting a format of the sampling instruction into a format of the system management bus protocol; the testing adapter is configured so that the ADC chip samples at least one of a voltage and a current of the sampling resistor to obtain a sampled analog signal, converts the sampled analog signal into a sampled digital signal, and sends the sampled digital signal to the second bridge chip based on the sampling instruction; and the testing adapter is further configured so that the second bridge chip sends the sampled digital signal to the host through the first interface circuit after converting a format of the sampled digital signal into a format of a protocol corresponding to the first interface circuit.

In an example implementation, the testing adapter further comprises a first general-purpose input/output (GPIO) interface circuit and a first switch; the first GPIO interface circuit is configured to be connected to a first target chip and be connected to the first switch, the first switch is in a power supply circuit of the testing adapter for supplying power to the memory apparatus, and the first target chip is one of the first bridge chip and the second bridge chip; and the testing adapter is configured so that the first target chip receives from the first interface circuit a third control instruction from the host, and triggers the first GPIO interface circuit to send a first level signal to the first switch based on the third control instruction, wherein the first level signal is configured to trigger the first switch to disconnect or connect to control power on/off of the memory apparatus.

In an example implementation, the testing adapter further comprises a second GPIO interface circuit; the second GPIO interface circuit is configured to be connected to a second target chip and be connected to the fourth interface circuit, and the second target chip is one of the first bridge chip and the second bridge chip; and the testing adapter is configured so that the second target chip receives from the first interface circuit a fourth control instruction from the host, and triggers the second GPIO interface circuit to send a second level signal to the memory apparatus through the fourth interface circuit based on the fourth control instruction.

In an example implementation, the first bridge chip has a first connector, and the first connector is configured to be connected to a programming device, so that the programming device rewrites a firmware of the first bridge chip through the first connector; and/or the second bridge chip has a second connector, and the second connector is configured to be connected to a programming device, so that the programming device rewrites a firmware of the second bridge chip through the second connector.

In a third aspect, a method for testing a memory apparatus is provided, wherein the method is performed by a testing adapter; the testing adapter comprises a first interface circuit, a second interface circuit, a third interface circuit, a fourth interface circuit, a first bridge chip, and a second bridge chip; the first interface circuit and the third interface circuit are configured to be connected to a host, respectively; the second interface circuit is configured to be connected to a debugging information interface circuit of the memory apparatus; the fourth interface circuit is configured to be connected to a data interface circuit of the memory apparatus; the first bridge chip is configured to be connected to the first interface circuit and be connected to the second interface circuit; and the second bridge chip is configured to be connected to the first interface circuit and be connected to the fourth interface circuit; and the method comprises: receiving, by the first bridge chip and the second bridge chip, a testing control instruction sent by the host; and performing, by the first bridge chip and the second bridge chip, a testing operation on the memory apparatus based on the testing control instruction.

In an example implementation, the testing adapter further comprises at least one system management bus slave device; and the second bridge chip is connected to the at least one system management bus slave device, and the at least one system management bus slave device is connected to the fourth interface circuit.

In an example implementation, the receiving, by the first bridge chip and the second bridge chip, the testing control instruction sent by the host comprises: the first bridge chip receiving from the first interface circuit a first control instruction from the host, and sending the first control instruction to the memory apparatus through the second interface circuit after converting a format of the first control instruction into a format of a protocol corresponding to the second interface circuit, wherein the first control instruction instructs the memory apparatus to perform a first testing-related operation; and the first bridge chip receiving from the second interface circuit debugging information sent by the memory apparatus, and sending the debugging information to the host through the first interface circuit after converting a format of the debugging information into a format of a protocol corresponding to the first interface circuit.

In an example implementation, the first control instruction comprises at least one of: an instruction to perform Universal Asynchronous Receiver/Transmitter (UART) testing; an instruction to perform Joint Test Action Group (JTAG) testing; and an instruction to perform Non-volatile Memory Expansion Management Interface (NVMe-MI) circuit testing related to Peripheral Component Interconnect Extension (PCI-E).

In an example implementation, the receiving, by the first bridge chip and the second bridge chip, the testing control instruction sent by the host comprises: the second bridge chip receiving from the first interface circuit a second control instruction from the host, and sending the second control instruction to a target slave device after converting a format of the second control instruction into a format of a system management bus protocol, wherein the target slave device is one or more of the at least one system management bus slave device; and the target slave device performing a second testing-related operation based on the second control instruction.

In an example implementation, the at least one system management bus slave device comprises a digital-to-analog conversion (DAC) chip and a power chip; the second bridge chip is configured to be connected to the DAC chip, the DAC chip is configured to be connected to the power chip, and the power chip is configured to be connected to the fourth interface circuit; the sending the second control instruction to the target slave device after converting the format of the second control instruction into the format of the system management bus protocol comprises: in the case where the second control instruction includes a bias voltage control instruction, the second bridge chip sending the bias voltage control instruction to the DAC chip after converting a format of the bias voltage control instruction into a format of the system management bus protocol; and the target slave device performing the second testing-related operation based on the second control instruction comprises: the DAC chip sending an analog voltage signal to the power chip after converting a digital voltage signal corresponding to the bias voltage control instruction into the analog voltage signal; and the power chip controlling a voltage output to the fourth interface circuit based on the analog voltage signal.

In an example implementation, the at least one system management bus slave device further comprises an analog-to-digital conversion (ADC) chip and a sampling resistor; the second bridge chip is configured to be connected to the ADC chip, the ADC chip is configured to be connected to the sampling resistor, and the sampling resistor is in a circuit between the power chip and the fourth interface circuit; the sending the second control instruction to the target slave device after converting the format of the second control instruction into the format of the system management bus protocol comprises: in the case where the second control instruction includes a sampling instruction, the second bridge chip sending the sampling instruction to the ADC chip after converting a format of the sampling instruction into a format of the system management bus protocol; the target slave device performing the second testing-related operation based on the second control instruction comprises: the ADC chip sampling at least one of a voltage and a current of the sampling resistor to obtain a sampled analog signal, converting the sampled analog signal into a sampled digital signal, and sending the sampled digital signal to the second bridge chip based on the sampling instruction; and the method further comprises: sending, by the second bridge chip, the sampled digital signal to the host through the first interface circuit after converting a format of the sampled digital signal into a format of a protocol corresponding to the first interface circuit.

In an example implementation, the testing adapter further comprises a first general-purpose input/output (GPIO) interface circuit and a first switch; the first GPIO interface circuit is configured to be connected to a first target chip and be connected to the first switch, the first switch is in a power supply circuit of the testing adapter for supplying power to the memory apparatus, and the first target chip is one of the first bridge chip and the second bridge chip; the receiving, by the first bridge chip and the second bridge chip, the testing control instruction sent by the host comprises: the first target chip receiving from the first interface circuit a third control instruction from the host; and the performing, by the first bridge chip and the second bridge chip, the testing operation on the memory apparatus based on the testing control instruction comprises: the first target chip triggering the first GPIO interface circuit to send a first level signal to the first switch based on the third control instruction, wherein the first level signal is configured to trigger the first switch to disconnect or connect to control power on/off of the memory apparatus.

In an example implementation, the testing adapter further comprises a second GPIO interface circuit; the second GPIO interface circuit is configured to be connected to a second target chip and be connected to the fourth interface circuit, and the second target chip is one of the first bridge chip and the second bridge chip; the receiving, by the first bridge chip and the second bridge chip, the testing control instruction sent by the host comprises: the second target chip receiving from the first interface circuit a fourth control instruction from the host; and the performing, by the first bridge chip and the second bridge chip, the testing operation on the memory apparatus based on the testing control instruction comprises: the second target chip triggering the second GPIO interface circuit to send a second level signal to the memory apparatus through the fourth interface circuit based on the fourth control instruction.

The technical aspects provided in the present disclosure may achieve the following advantageous effects.

The present disclosure provides a testing adapter for testing a memory apparatus, wherein the testing adapter is respectively connected to a host and a memory apparatus through four interface circuits. The testing adapter includes a first bridge chip and a second bridge chip that are connected to the four interface circuits, respectively. During the testing process of the memory apparatus, the first bridge chip and the second bridge chip in the testing adapter may perform a testing operation on the memory apparatus based on a testing control instruction sent by the host. In the above aspect, the testing adapter does not rely on MCU, and instead uses the bridge chips to test the memory apparatus. Compared to a test card that relies on MCU, the circuit complexity of the testing adapter provided in the present disclosure is lower. Correspondingly, when using the testing adapter to test a memory apparatus, complex software control logic is not required, resulting in lower testing complexity and improved testing efficiency for a memory apparatus.

The above are only example implementations of the present disclosure, and is not intended to limit the present disclosure. Any modifications, equivalent substitutions, improvements, etc. made within the spirit and principles of the present disclosure shall be included in the scope of the present disclosure.

What is claimed is:

1. A testing adapter, comprising:
a first interface circuit configured to be connected to a host;
a second interface circuit configured to be connected to a debugging information interface circuit of a memory apparatus;
a third interface circuit configured to be connected to the host;
a fourth interface circuit configured to be connected to a data interface circuit of the memory apparatus;
a first bridge chip configured to be connected to the first interface circuit and to the second interface circuit; and
a second bridge chip configured to be connected to the first interface circuit and to the fourth interface circuit, wherein the first bridge chip and the second bridge chip are configured to perform a testing operation on the memory apparatus based on a testing control instruction from the host.

2. The testing adapter of claim 1, further comprising a system management bus slave device, wherein:
the second bridge chip is configured to be connected to the system management bus slave device; and
the system management bus slave device is configured to be connected to the fourth interface circuit.

3. The testing adapter of claim 1, wherein the first bridge chip is configured to:
receive, through the first interface circuit, a first control instruction from the host;
send the first control instruction to the memory apparatus through the second interface circuit after converting a format of the first control instruction into a format of a protocol corresponding to the second interface circuit, the first control instruction to instruct the memory apparatus to perform a first testing-related operation;
receive, through the second interface circuit, debugging information from the memory apparatus; and
send the debugging information to the host through the first interface circuit after converting a format of the debugging information into a format of a protocol corresponding to the first interface circuit.

4. The testing adapter of claim 3, wherein the first control instruction comprises at least one of:
an instruction to perform Universal Asynchronous Receiver/Transmitter (UART) testing;
an instruction to perform Joint Test Action Group (JTAG) testing; or
an instruction to perform Non-volatile Memory Expansion Management Interface (NVMe-MI) circuit testing related to Peripheral Component Interconnect Extension (PCI-E).

5. The testing adapter of claim 2, wherein:
the second bridge chip is configured to:
receive, through the first interface circuit, a second control instruction from the host; and
send the second control instruction to a target slave device after converting a format of the second control instruction into a format of a system management bus protocol, wherein the target slave device is the system management bus slave device; and
the target slave device is configured to perform a second testing-related operation based on the second control instruction.

6. The testing adapter of claim 5, wherein:
the system management bus slave device comprises a digital-to-analog conversion (DAC) chip and a power chip;
based on the second control instruction including a bias voltage control instruction, the second bridge chip is to send the bias voltage control instruction to the DAC chip after converting a format of the bias voltage control instruction into a format of the system management bus protocol;
the DAC chip is configured to send an analog voltage signal to the power chip after converting a digital voltage signal corresponding to the bias voltage control instruction into the analog voltage signal; and
the power chip is configured to control a voltage output to the fourth interface circuit based on the analog voltage signal.

7. The testing adapter of claim 6, wherein:
the system management bus slave device further comprises an analog-to-digital conversion (ADC) chip and a sampling resistor;
based on the second control instruction including a sampling instruction, the second bridge chip is to send the sampling instruction to the ADC chip after converting a format of the sampling instruction into a format of the system management bus protocol;
the ADC chip is configured to:
sample at least one of a voltage or a current of the sampling resistor to obtain a sampled analog signal;
convert the sampled analog signal into a sampled digital signal; and
send the sampled digital signal to the second bridge chip based on the sampling instruction; and
the second bridge chip is configured to send the sampled digital signal to the host through the first interface circuit after converting a format of the sampled digital signal into a format of a protocol corresponding to the first interface circuit.

8. The testing adapter of claim 1, further comprising:
a first general-purpose input/output (GPIO) interface circuit configured to be connected to a first target chip; and
a first switch configured to be connected to the first GPIO, wherein:
the first switch is in a power supply circuit of the testing adapter to supply power to the memory apparatus;
the first target chip is one of the first bridge chip or the second bridge chip; and
the first target chip is configured to:
receive, through the first interface circuit, a third control instruction from the host; and
trigger the first GPIO interface circuit to send a first level signal to the first switch based on the third control instruction, wherein the first level signal is configured to trigger the first switch to control a power state of the memory apparatus.

9. The testing adapter of claim 1, further comprising a second GPIO interface circuit, wherein:
the second GPIO interface circuit is configured to be connected to a second target chip and to the fourth interface circuit;
the second target chip is one of the first bridge chip or the second bridge chip; and
the second target chip is configured to:
receive, through the first interface circuit, a fourth control instruction from the host; and
trigger the second GPIO interface circuit to send a second level signal to the memory apparatus through the fourth interface circuit based on the fourth control instruction.

10. The testing adapter of claim 1, wherein at least one of:
the first bridge chip has a first connector, the first connector is configured to be connected to a programming device, the programming device to rewrite firmware of the first bridge chip through the first connector; or
the second bridge chip has a second connector, the second connector is configured to be connected to the programming device, the programming device to rewrite firmware of the second bridge chip through the second connector.

11. A testing system to test a memory apparatus, the testing system comprising:
a testing adapter; and
a host, wherein:
the testing adapter comprises a first interface circuit, a second interface circuit, a third interface circuit, a fourth interface circuit, a first bridge chip, and a second bridge chip;
the first interface circuit and the third interface circuit are configured to be connected to the host, the second interface circuit is configured to be connected to a debugging information interface circuit of the memory apparatus, and the fourth interface circuit is configured to be connected to a data interface circuit of the memory apparatus;
the first bridge chip is configured to be connected to the first interface circuit and to the second interface circuit, and the second bridge chip is configured to be connected to the first interface circuit and to the fourth interface circuit;
the host is configured to send a testing control instruction to the testing adapter; and
the first bridge chip and the second bridge chip are configured to perform a testing operation on the memory apparatus based on the testing control instruction.

12. The testing system of claim 11, wherein:
the testing adapter further comprises a system management bus slave device;
the second bridge chip is configured to be connected to the system management bus slave device; and
the system management bus slave device is configured to be connected to the fourth interface circuit.

13. The testing system of claim 11, wherein the first bridge chip is to:
receive, through the first interface circuit, a first control instruction from the host;
send the first control instruction to the memory apparatus through the second interface circuit after converting a format of the first control instruction into a format of a protocol corresponding to the second interface circuit, the first control instruction to instruct the memory apparatus to perform a first testing-related operation;
receive, through the second interface circuit, debugging information from the memory apparatus; and
send the debugging information to the host through the first interface circuit after converting a format of the debugging information into a format of a protocol corresponding to the first interface circuit.

14. The testing system of claim 13, wherein the first control instruction comprises at least one of:
an instruction to perform Universal Asynchronous Receiver/Transmitter (UART) testing;
an instruction to perform Joint Test Action Group (JTAG) testing; or
an instruction to perform Non-volatile Memory Expansion Management Interface (NVMe-MI) circuit testing related to Peripheral Component Interconnect Extension (PCI-E).

15. The testing system of claim 12, wherein:
the second bridge chip is to:
receive, through the first interface circuit, a second control instruction from the host; and
send the second control instruction to a target slave device after converting a format of the second control instruction into a format of a system management bus protocol, the target slave device is the system management bus slave device; and
the target slave device is to perform a second testing-related operation based on the second control instruction.

16. The testing system of claim 15, wherein the system management bus slave device comprises:
a digital-to-analog conversion (DAC) chip configured to be connected to the second bridge chip; and
a power chip configured to be connected to the DAC chip and to the fourth interface circuit, wherein:
based on the second control instruction including a bias voltage control instruction, the second bridge chip is to send the bias voltage control instruction to the DAC chip after converting a format of the bias voltage control instruction into a format of the system management bus protocol;
the DAC chip is to send an analog voltage signal to the power chip after converting a digital voltage signal corresponding to the bias voltage control instruction into the analog voltage signal; and
the power chip is to control a voltage output to the fourth interface circuit based on the analog voltage signal.

17. The testing system of claim 16, wherein the system management bus slave device comprises:
an analog-to-digital conversion (ADC) chip configured to be connected to the second bridge chip; and
a sampling resistor configured to be connected to the ADC chip, the sampling resistor in a circuit between the power chip and the fourth interface circuit, wherein:
based on the second control instruction including a sampling instruction, the second bridge chip is to send the sampling instruction to the ADC chip after converting a format of the sampling instruction into a format of the system management bus protocol;
the ADC chip is configured to:
sample at least one of a voltage or a current of the sampling resistor to obtain a sampled analog signal;
convert the sampled analog signal into a sampled digital signal; and
send the sampled digital signal to the second bridge chip based on the sampling instruction; and
the second bridge chip is configured to send the sampled digital signal to the host through the first interface circuit after converting a format of the sampled digital signal into a format of a protocol corresponding to the first interface circuit.

18. The testing system of claim 11, wherein the testing adapter further comprises:
a first general-purpose input/output (GPIO) interface circuit configured to be connected to a first target chip; and
a first switch configured to be connected to the GPIO interface, wherein:
the first switch is in a power supply circuit of the testing adapter to supply power to the memory apparatus;
the first target chip is one of the first bridge chip or the second bridge chip; and
the first target chip is configured to:
receive, through the first interface circuit, a third control instruction from the host; and
trigger the first GPIO interface circuit to send a first level signal to the first switch based on the third control instruction, wherein the first level signal is configured to trigger the first switch to control a power state of the memory apparatus.

19. The testing system of claim 11, wherein the testing adapter further comprises a second GPIO interface circuit configured to be connected to a second target chip and to the fourth interface circuit, wherein:
the second target chip is one of the first bridge chip or the second bridge chip; and
the second target chip is to:
receive, through the first interface circuit, a fourth control instruction from the host; and
trigger the second GPIO interface circuit to send a second level signal to the memory apparatus through the fourth interface circuit based on the fourth control instruction.

20. A method for testing a memory apparatus, the method comprising:
receiving a testing control instruction from a host, the receiving of the testing control instruction includes:
receiving the testing control instruction at a first bridge chip of a testing adapter, the first bridge chip connected to a first interface circuit and a second interface circuit of the testing adapter, the testing adapter including a third interface circuit connected to the host; and
receiving the testing control instruction at a second bridge chip of the testing adapter, the second bridge chip connected to the first interface circuit and a fourth interface circuit of the testing adapter; and
performing, by the first bridge chip and the second bridge chip, a testing operation on the memory apparatus based on the testing control instruction.
